(19) United States
(12) Patent Application Publication
(10) Pub. No.: US 2025/0324788 A1
(43) Pub. Date: Oct. 16, 2025

(54) SEMICONDUCTOR DEVICE AND IMAGING DEVICE

(71) Applicant: SONY SEMICONDUCTOR SOLUTIONS CORPORATION, Kanagawa (JP)

(72) Inventors: Takashi YOKOYAMA, Kanagawa (JP); Masaki HANEDA, Kanagawa (JP)

(73) Assignee: SONY SEMICONDUCTOR SOLUTIONS CORPORATION, Kanagawa (JP)

(21) Appl. No.: 18/871,927

(22) PCT Filed: Jun. 14, 2023
(86) PCT No.: PCT/JP2023/022129

§ 371 Date: Dec. 5, 2024

(30) Foreign Application Priority Data
Jun. 16, 2022 (JP) 2022-097554

(51) Int. Cl. H10F 39/00; H04N 25/772

(52) U.S. Cl. CPC H10F 39/80373; H04N 25/772; H10F 39/811

(57) ABSTRACT

A first semiconductor device according to an embodiment of the present disclosure includes: a first structure layer having a chip-on-wafer structure and being mounted with a first circuit chip and a second circuit chip that have different technology nodes; and a second structure layer having a chip-on-wafer structure and being stacked on the first structure layer.

### TECHNICAL FIELD

The present disclosure relates to a semiconductor device having a three-dimensional structure and an imaging device.

### BACKGROUND ART

For example, PTL 1 discloses an image sensing device in which a first substrate structure including a pixel region and a second substrate structure including a logic circuit are bonded to each other to implement the second substrate structure and a semiconductor chip using an electrically-conductive bump.

### CITATION LIST

### Patent Literature

PTL 1: Japanese Unexamined Patent Application Publication No. 2019-68049

### SUMMARY OF THE INVENTION

Incidentally, an imaging device is desired to have higher functionality.

It is desirable to provide a semiconductor device and an imaging device that enable higher functionality.

A first semiconductor device according to an embodiment of the present disclosure includes: a first structure layer having a chip-on-wafer structure and being mounted with a first circuit chip and a second circuit chip that have different technology nodes; and a second structure layer having a chip-on-wafer structure and being stacked on the first structure layer.

An imaging device according to an embodiment of the present disclosure includes: a sensor substrate including one or a plurality of sensor pixels that performs photoelectric conversion; and the semiconductor device according to an embodiment of the present disclosure stacked on the sensor substrate.

A second semiconductor device according to an embodiment of the present disclosure includes: a first structure layer mounted with a first circuit chip and a second circuit chip that have different technology nodes; and a second structure layer stacked on the first structure layer and being mounted with a plurality of chips.

In the first semiconductor device and the imaging device according to the respective embodiments of the present disclosure, the first structure layer having the chip-on-wafer structure mounted with the first circuit chip and the second circuit chip that have different technology nodes is stacked on the second structure layer having the chip-on-wafer structure. In addition, in the second semiconductor device according to the embodiment of the present disclosure, the first structure layer mounted with the first circuit chip and the second circuit chip that have different technology nodes is stacked on the second structure layer mounted with a plurality of chips. This enables mounting of a plurality of chips having different functions.

### BRIEF DESCRIPTION OF THE DRAWINGS

FIG. 1 is a schematic cross-sectional view of a configuration of an imaging device according to an embodiment of the present disclosure.

FIG. 2 is an exploded perspective view of an example of a schematic configuration of the imaging device illustrated in FIG. 1.

FIG. 3 is a diagram illustrating an example of a circuit configuration of the imaging device illustrated in FIG. 1.

FIG. 4 is an explanatory schematic view of different technology nodes.

FIG. 5A is an exploded perspective view of a coupling mode of a pixel array section of the imaging device illustrated in FIG. 1.

FIG. 5B is an explanatory diagram of each coupling of a sensor pixel, an analog circuit of a first CoW layer, and a logic circuit of a second CoW layer illustrated in FIG. 5A.

FIG. 6 is an exploded perspective view of an example of a coupling mode of a peripheral section of the imaging device illustrated in FIG. 1.

FIG. 7 is an exploded perspective view of another embodiment of the coupling mode of the peripheral section of the imaging device illustrated in FIG. 1.

FIG. 8A is an explanatory schematic cross-sectional view of an example of a manufacturing step of the imaging device illustrated in FIG. 1.

FIG. 8B is a schematic cross-sectional view of a step subsequent to FIG. 8A.

FIG. 8C is a schematic cross-sectional view of a step subsequent to FIG. 8B.

FIG. 8D is a schematic cross-sectional view of a step subsequent to FIG. 8C.

FIG. 8E is a schematic cross-sectional view of a step subsequent to FIG. 8D.

FIG. 8F is a schematic cross-sectional view of a step subsequent to FIG. 8E.

FIG. 9 is a schematic cross-sectional view of a configuration of an imaging device according to Modification Example 1 of the present disclosure.

FIG. 10A is an explanatory schematic cross-sectional view of an example of a manufacturing step of the imaging device illustrated in FIG. 9.

FIG. 10B is a schematic cross-sectional view of a step subsequent to FIG. 10A.

FIG. 10C is a schematic cross-sectional view of a step subsequent to FIG. 10B.

FIG. 10D is a schematic cross-sectional view of a step subsequent to FIG. 10C.

FIG. 10E is a schematic cross-sectional view of a step subsequent to FIG. 10D.

FIG. 10F is a schematic cross-sectional view of a step subsequent to FIG. 10E.

FIG. 10G is a schematic cross-sectional view of a step subsequent to FIG. 10F.

FIG. 10H is a schematic cross-sectional view of a step subsequent to FIG. 10G.

FIG. 11 is an exploded perspective view of an example of a schematic configuration of an imaging device according to Modification Example 2 of the present disclosure.

FIG. 12 is an exploded perspective view of an example of a coupling mode of a peripheral section of the imaging device illustrated in FIG. 11.

FIG. 13 is an exploded perspective view of an example of a schematic configuration of an imaging device according to Modification Example 3 of the present disclosure.

FIG. 14 is an exploded perspective view of an example of a schematic configuration of an imaging device according to Modification Example 4 of the present disclosure.

FIG. 15 is an exploded perspective view of an example of a schematic configuration of an imaging device according to Modification Example 5 of the present disclosure.

FIG. 16 is an exploded perspective view of another example of the schematic configuration of the imaging device according to Modification Example 5 of the present disclosure.

FIG. 17 is a schematic cross-sectional view of a configuration of an imaging device according to Modification Example 6 of the present disclosure.

FIG. 18 is a diagram illustrating an example of a schematic configuration of an imaging system including the imaging device according to any of the foregoing embodiment and Modification Examples 1 to 6.

FIG. 19 is a diagram illustrating an example of an imaging procedure in the imaging system in FIG. 18.

FIG. 20 is a block diagram depicting an example of schematic configuration of a vehicle control system.

FIG. 21 is a diagram of assistance in explaining an example of installation positions of an outside-vehicle information detecting section and an imaging section.

FIG. 22 is a view depicting an example of a schematic configuration of an endoscopic surgery system.

FIG. 23 is a block diagram depicting an example of a functional configuration of a camera head and a camera control unit (CCU).

FIG. 24 is a schematic cross-sectional view of a configuration of an imaging device according to Modification Example 7 of the present disclosure.

FIG. 25 is an example of an equivalent circuit diagram of a pixel array section of the imaging device illustrated in FIG. 24.

FIG. 26 is another example of the equivalent circuit diagram of the pixel array section of the imaging device illustrated in FIG. 24.

FIG. 27 is a schematic cross-sectional view of a configuration of an imaging device according to Modification Example 8 of the present disclosure.

FIG. 28 is a schematic cross-sectional view of a configuration of an imaging device according to Modification Example 9 of the present disclosure.

FIG. 29 is a schematic cross-sectional view of a configuration of an imaging device according to Modification Example 10 of the present disclosure.

### MODES FOR CARRYING OUT THE INVENTION

Hereinafter, description is given in detail of an embodiment of the present disclosure with reference to the drawings. The following description is merely a specific example of the present disclosure, and the present disclosure should not be limited to the following aspects. Moreover, the present disclosure is not limited to arrangements, dimensions, dimensional ratios, and the like of each component illustrated in the drawings. It is to be noted that the description is given in the following order.
1. Embodiment (An example of an imaging device including a chip-on-wafer mounted with a plurality of circuit chips with different technology nodes immediately below a sensor substrate)
   1-1. Configuration of Imaging Device
   1-2. Manufacturing Method of Imaging Device
   1-3. Workings and Effects
2. Modification Examples
   2-1. Modification Example 1 (Another example of a structure of the imaging device)
   2-2. Modification Example 2 (An example of further mounting circuit chips with different technology nodes on a chip-on-wafer layer immediately below the sensor substrate)
   2-3. Modification Example 3 (An example of further mounting a memory chip on the chip-on-wafer layer immediately below the sensor substrate)
   2-4. Modification Example 4 (An example of mounting a portion of an analog circuit provided in the chip-on-wafer layer immediately below the sensor substrate, in a still lower chip-on-wafer layer)
   2-5. Modification Example 5 (An example of mounting a chip-wafer layer of a multilayer structure)
   2-6. Modification Example 6 (An example of stacking chip-on-wafer layers of three or more layers)
   2-7. Modification Example 7 (Another example of the structure of the imaging device)
   2-8. Modification Example 8 (Another example of the structure of the imaging device)
   2-9. Modification Example 9 (Another example of the structure of the imaging device)
   2-10. Modification Example 10 (Another example of the structure of the imaging device)
3. Application Example
4. Practical Application Examples

### 1. Embodiment

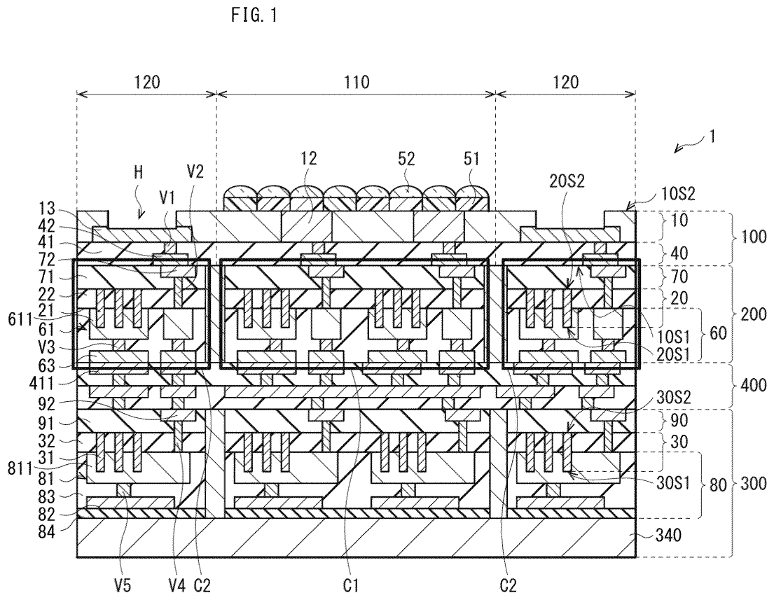

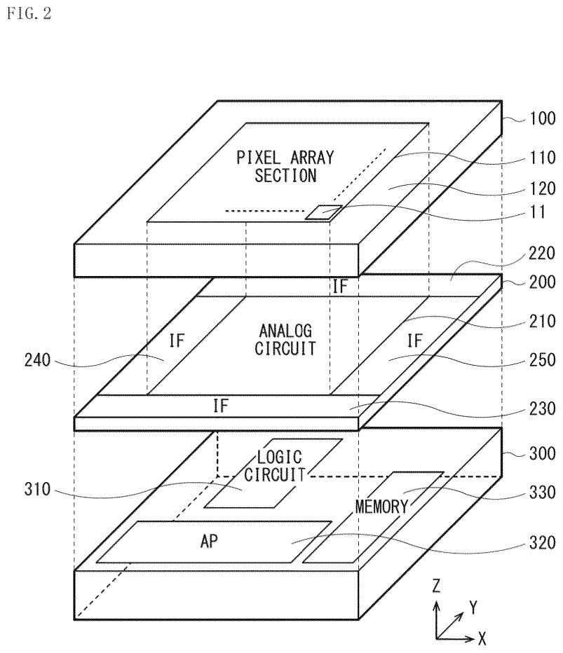

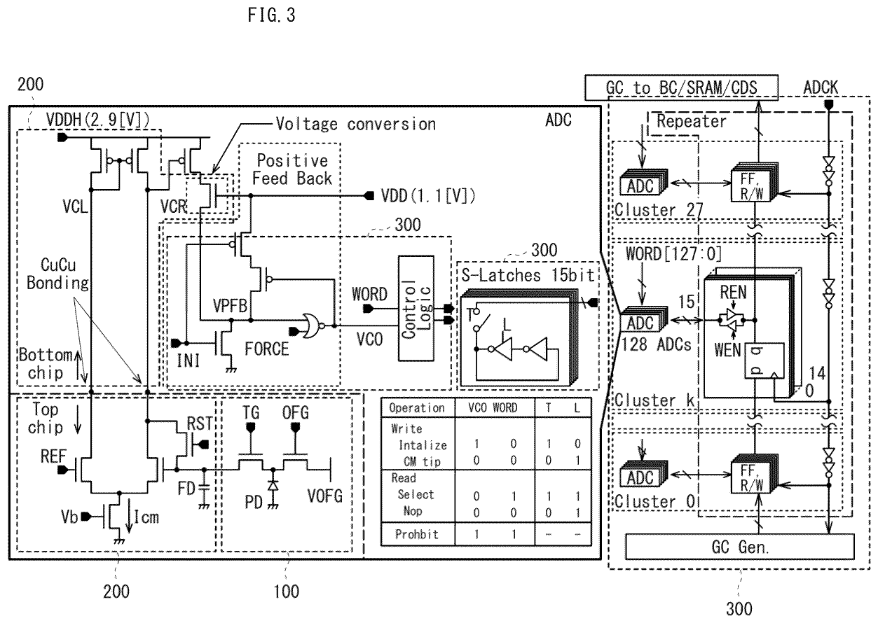

FIG. 1 schematically illustrates an example of a cross-sectional configuration of an imaging device (an imaging device 1) according to an embodiment of the present disclosure. FIG. 2 is an exploded perspective view of a schematic configuration of the imaging device 1 illustrated in FIG. 1. FIG. 3 illustrates an example of a circuit configuration of the imaging device 1. The imaging device 1 is an imaging device having a three-dimensional structure in which, below a sensor substrate 100, two layers (a first CoW layer 200 and a second CoW layer 300) having a chip-on-wafer (CoW) structure are stacked. The first CoW layer 200 and the second CoW layer 300 are stacked in this order below the sensor substrate 100, and the first CoW layer 200 arranged immediately below the sensor substrate 100 is mounted with circuit chips C1 and C2 with different technology nodes.

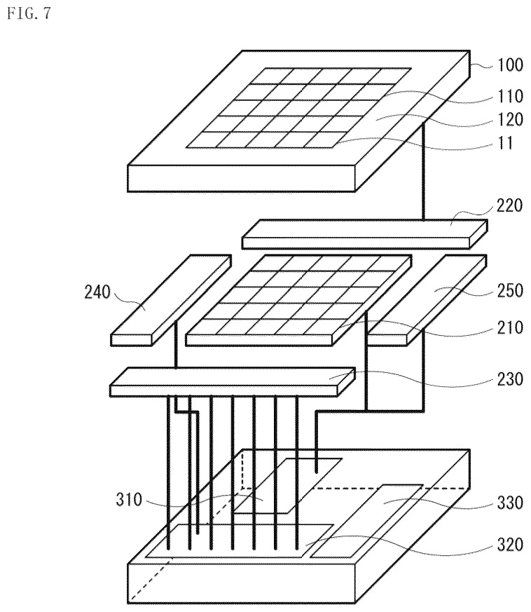

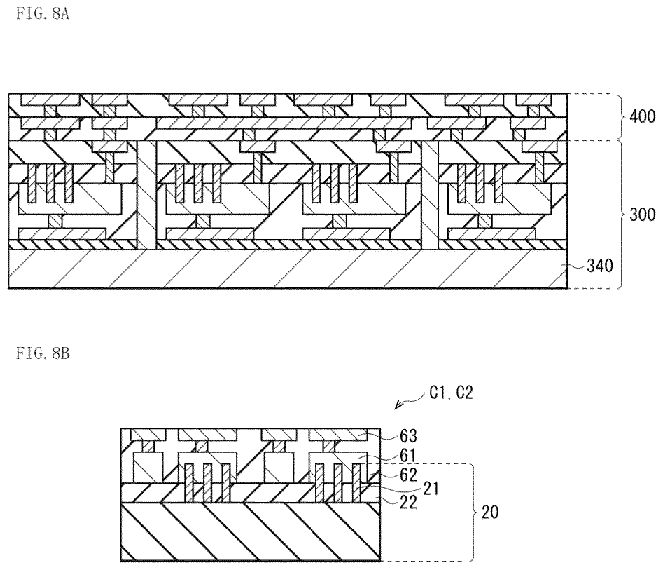

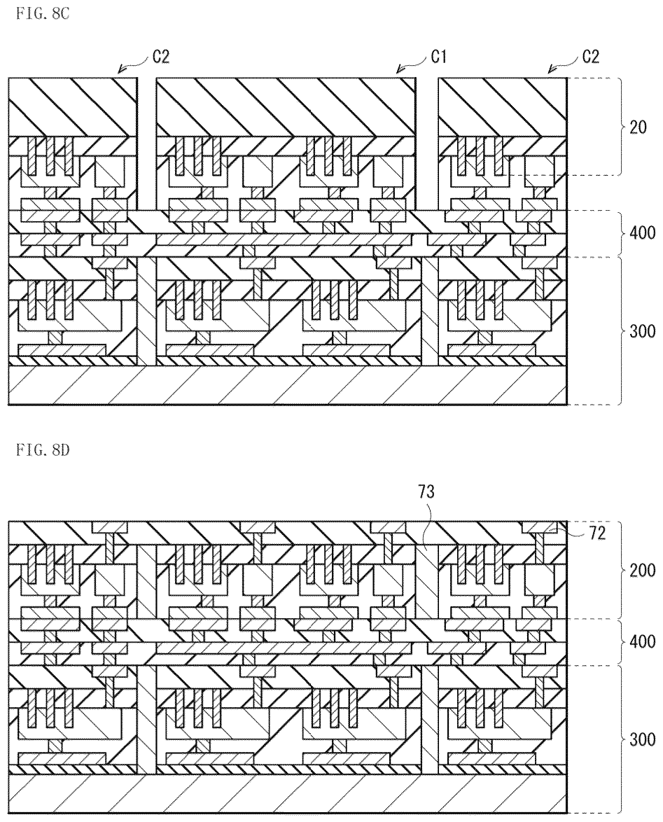

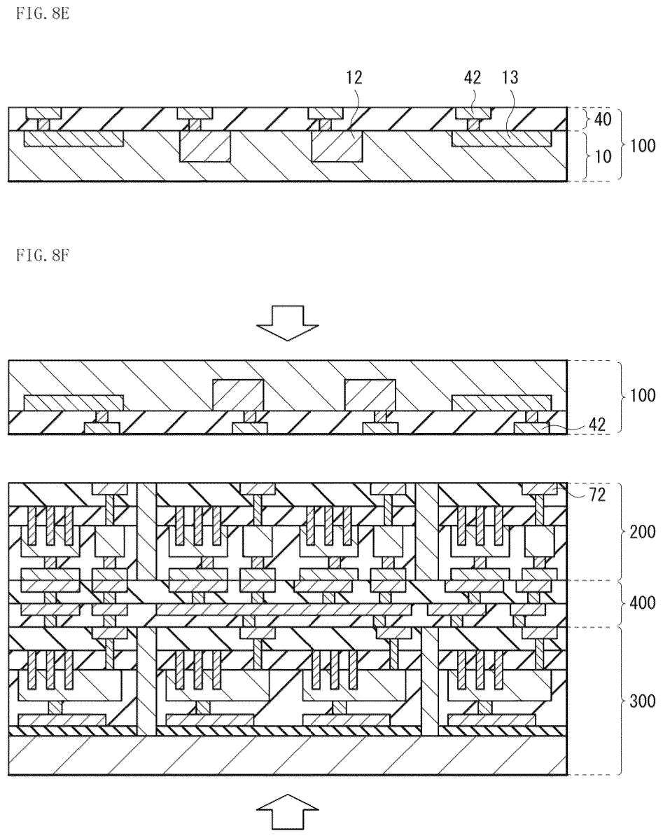

Here, the first CoW layer 200 corresponds to a specific example of a “first structure layer” in an embodiment of the present disclosure, and the second CoW layer 300 corresponds to a specific example of a “second structure layer” in an embodiment of the present disclosure. As is apparent from FIG. 1 and FIGS. 8A to 8F, 9, and 10A to 10H mentioned later, the second CoW layer 300 includes, for example, a support substrate 340, a plurality of chips stacked on the support substrate 340, and an insulating film 85. At least some of the plurality of chips are embedded by the insulating film 85, and the insulating film 85 is embedded between adjacent chips in the present embodiment. The first CoW layer 200 includes the circuit chip C1 and the circuit chip C2 stacked on the second CoW layer 300, and an insulating film 73. At least some of the circuit chip C1 and the circuit chip C2 are embedded by the insulating film 73, and the insulating film 85 is embedded between the circuit chip C1 and the circuit chip C2 adjacent to each other in the present embodiment. In addition, as is apparent from FIG. 1 and FIGS. 8A to 8F mentioned later, the circuit chip C1 and the circuit chip C2 each include, for example, a semiconductor layer 20 and wiring layers 60 and 70. The circuit chip C1 and the circuit chip C2 have different sizes, as is apparent from FIG. 1; for example, the circuit chip C1 is larger than the circuit chip C2.

### (1-1. Configuration of Imaging Device)

The imaging device 1 is a so-called back side illumination imaging device that receives light from a side of a back surface of the sensor substrate 100 (e.g., a back surface (a second surface 10S2) of a semiconductor substrate 10 constituting the sensor substrate 100). In the imaging device 1, as described above, the sensor substrate 100, the first CoW layer 200, and the second CoW layer 300 are stacked in this order.

The sensor substrate 100 includes the semiconductor substrate 10 having a first surface (front surface) 10S1 and the second surface (back surface) 10S2 opposed to each other, and a multilayer wiring layer 40 provided on a side of the first surface 10S1 of the semiconductor substrate 10.

The semiconductor substrate 10 includes a pixel array section 110 in which a plurality of sensor pixels 11 is arranged in array, and a peripheral section 120 provided around the pixel array section 110. In the pixel array section 110, for example, a photodiode PD (a light-receiving element 12) that performs photoelectric conversion is formed to be embedded in each of the plurality of sensor pixels 11. Further, although not illustrated, the first surface 10S1 of the semiconductor substrate 10 is provided with, for example, one floating diffusion FD, transfer transistor TR, and the like for each of the sensor pixels 11 or for every plurality of sensor pixels 11. In the peripheral section 120, for example, a pad electrode 13 for electrical coupling to the outside is provided on the side of the first surface 10S1 of the semiconductor substrate 10. The pad electrode 13 is exposed to a side of the second surface 10S2 of the semiconductor substrate 10 through an opening H provided on the side of the second surface 10S2.

In the multilayer wiring layer 40, for example, wiring coupled to the floating diffusion FD, wiring including a gate of the transfer transistor TR, and the like are formed inside a layer of an interlayer insulating layer 41. One or a plurality of pad sections 42 for use in bonding and electrical coupling to the first CoW layer 200, for example, is exposed to a surface of the multilayer wiring layer 40 (specifically, a surface of the interlayer insulating layer 41). Although not illustrated, the pad section 42 is coupled to the floating diffusion FD or the gate of the transfer transistor TR through a via V1, for example.

A color filter 51 and a light-receiving lens 52 are provided, for example, on the side of the second surface 10S2 of the semiconductor substrate 10.

As described above, the first CoW layer 200 is mounted with the circuit chips C1 and C2 with different technology nodes. Here, the phrase “with different technology nodes” means that there is a difference, for example, in at least one of a minimum power supply voltage (Vdd), a film thickness of a gate insulating film of a transistor constituting each circuit, a gate length (lg) and a minimum gate pitch (Pg) of the transistor constituting each circuit, or a wiring width and a minimum wiring pitch (Pm) of wiring provided in each circuit, which are illustrated in FIG. 4. Table 1 summarizes an example of a minimum power supply voltage (Vdd), a film thickness of a gate insulating film, a gate length (lg), a minimum gate pitch (Pg), a wiring width, and a minimum wiring pitch (Pm) in each of technology nodes (22 nm node, 12 nm node, 7 nm node, and 5 nm node).

TABLE 1

| Technology Node | 22 nm | 12 nm | 7 nm | 5 nm |
|---|---|---|---|---|
| Gate Length (lg) | 30 | 25 | 20 | 15 |
| Minimum Gate Pitch (Pg) | 90 | 70 | 54 | 44 |
| Wiring Width | 40 | 26 | 18 | 16 |
| Minimum Wiring Pitch (Pm) | 80 | 52 | 36 | 32 |
| Gate Insulating Film | 1.6/0.8 | 1.3/1.1 | | 1.3/1.1 |
| Thickness | | | | |
| Minimum Power Supply | 0.9 | 0.8 | 0.7 | 0.6 |
| Voltage (V) | | | | |

As illustrated in FIG. 2, the first CoW layer 200 is mounted with, for example, an analog circuit 210 and four interface (IF) circuits 220, 230, 240, and 250. The analog circuit 210 includes a circuit configuration that amplifies a pixel signal generated in the plurality of sensor pixels 11 and converts the amplified pixel signal into a digital signal. Specifically, the analog circuit 210 is a portion of a controller or the like that controls each section inside the imaging device 1 or an analog-to-digital converter (ADC), for example, of the imaging device 1, and has a circuit configuration to be supplied with a power supply voltage for an analog circuit. As an example, the analog circuit 210 includes various transistors (pixel circuits) that reads an analog pixel signal from the sensor pixel 11, a vertical drive circuit that drives, on a row-by-row basis, the sensor pixels 11 arrayed in a two-dimensional grid manner in row and column directions, a comparator and a counter of the ADC, a reference voltage supply section that supplies a reference voltage to the comparator, a Phase Locked Loop (PLL) circuit, and the like. The IF circuits 220, 230, 240, and 250 each include a circuit configuration to output, to the outside, data (digital signal) processed in a logic circuit 310 or the like described later.

The analog circuit 210 is configured as the circuit chip C1 with a technology node of an older generation than, for example, the 22 nm node enabling mounting of a high-voltage drive transistor that performs analog processing. The IF circuits 220, 230, 240, and 250 are each configured as the circuit chip C2 with the most advanced technology node, e.g., the 7 nm node or thereafter that enables low-voltage operation. The analog circuit 210 (circuit chip C1) is arranged, for example, in the pixel array section 110 in a plan view. The IF circuits 220, 230, 240, and 250 (circuit chips C2) are arranged, for example, in the peripheral section 120 in a plan view.

The circuit chips C1 and C2 each include the semiconductor layer 20 and the wiring layers 60 and 70. The semiconductor layer 20 has a front surface 20S1 and a back surface 20S2 opposed to each other. The wiring layer 60 is provided on a side of the front surface 20S1, and the wiring layer 70 is provided on a side of the back surface 20S2. The sensor substrate 100 and the first CoW layer 200 are stacked, with the multilayer wiring layer 40 and the wiring layer 70 interposed therebetween; the multilayer wiring layer 40 is provided on the side of the first surface 10S1 of the semiconductor substrate 10, and the wiring layer 70 is provided on the side of the back surface 20S2 of the semiconductor layer 20. That is, the sensor substrate 100 and the first CoW layer 200 are stacked face-to-back.

The transistor provided in the circuit chips C1 and C2 has a Fin-FET structure, for example. The Fin-FET includes a gate 611 and a plurality of fins 21 including the semiconductor layer 20, for example.

Each of the plurality of fins 21 has a planar shape. For example, the plurality of fins 21 is arranged in an X-axis direction and is erected in a Y-axis direction. For example, the plurality of fins 21 penetrates an element separation region 22 from an insulating film such as SiO2, and a side surface and a top surface of the plurality of penetrating fins 21 are covered with a gate insulating film (unillustrated) configured by HfSiO, HfSiON, TaO, TaON, or the like, for example. The gate 611 extends to straddle the plurality of fins 21 in the X-axis direction intersecting a direction in which the fins 21 are erected (Y-axis direction). In the fin 21, a channel region is formed at an intersecting part with the gate 611, and source/drain regions are formed at respective ends sandwiching the channel region. The semiconductor layer 20 is divided into a plurality of semiconductor layers 20 by the element separation region 22 having a Shallow Trench Isolation (STI) structure, or a Deep Trench Isolation (DTI) or Full Trench Isolation (FTI) structure, for example.

In the wiring layer 60, wiring 61 including the above-described gate 611 is formed inside an interlayer insulating layer 62. For example, one or a plurality of pad sections 63 for use in bonding and electrical coupling to the second CoW layer 300 is exposed to a surface of the wiring layer 60 (specifically, a surface of the interlayer insulating layer 62). The pad section 63 is coupled to the wiring 61 such as the gate 611 through a via V3, for example. In the wiring layer 70, for example, one or a plurality of pad sections 72 for use in bonding and electrical coupling to the sensor substrate 100 is exposed to a surface of an interlayer insulating layer 71. The pad section 72 is coupled to the wiring 61 through a via V2, for example.

As illustrated in FIG. 2, in the second CoW layer 300, for example, a logic circuit 310, an application processor (AP) 320, and a memory 330 are mounted on the support substrate 340. The logic circuit 310 includes, for example, a circuit configuration that performs correction and signal modulation on a digital signal converted in the analog circuit 210. The application processor (AP) 320 includes, for example, a circuit configuration that enables machine learning such as a deep neural network (DNN). The memory 330 includes, for example, a circuit configuration that stores data obtained by machine learning of the application processor (AP) 320 such as Dynamic Random Access Memory (DRAM). The logic circuit 310, the application processor (AP) 320, and the memory 330 include respective circuit chips with different technology nodes, for example.

The circuit chips constituting the logic circuit 310, the application processor (AP) 320, and the memory 330 each have a semiconductor layer 30 and wiring layers 80 and 90. The semiconductor layer 30 includes a front surface 30S1 and a back surface 30S2 opposed to each other. The wiring layer 80 is provided on a side of the front surface 30S1, and the wiring layer 90 is provided on a side of the back surface 30S2. The first CoW layer 200 and the second CoW layer 300 are stacked, with the wiring layer 60 and the wiring layer 90 interposed therebetween; the wiring layer 60 is provided on the side of the front surface 20S1 of the semiconductor layer 20, and the wiring layer 90 is provided on the side of the back surface 30S2 of the semiconductor layer 30. That is, the first CoW layer 200 and the second CoW layer 300 are stacked face-to-back.

In the wiring layer 80, wiring 81 including a gate 811, wiring 82, and a via V5 that couples the wiring 81 and the wiring 82 to each other are formed inside an interlayer insulating layer 83, and an insulating layer 84 is provided on the interlayer insulating layer 83. In the wiring layer 90, for example, one or a plurality of pad sections 92 for use in bonding and electrical coupling to the first CoW layer 200 is exposed to a surface of an interlayer insulating layer 91. The pad section 92 is coupled to the wiring 81 through a via 4, for example. On the wiring layer 90, there is further provided a multilayer wiring layer 400 as a common layer for a plurality of circuit chips mounted on the second CoW layer 300. A pad section 411 is exposed to the surface of the multilayer wiring layer 40 on a side of the first CoW layer 200.

The sensor substrate 100, the first CoW layer 200, and the second CoW layer 300 are electrically coupled to each other by metal bonding (e.g., Cu—Cu bonding). Specifically, the sensor substrate 100 and the first CoW layer 200 are electrically coupled to each other by bonding between the one or the plurality of pad sections 42 and the one or the plurality of pad sections 72 provided respectively, and the first CoW layer 200 and the second CoW layer 300 (particularly, the multilayer wiring layer 400 provided on the second CoW layer 300) are electrically coupled to each other by bonding between the one or the plurality of pad sections 63 and one or a plurality of pad sections 411 provided respectively.

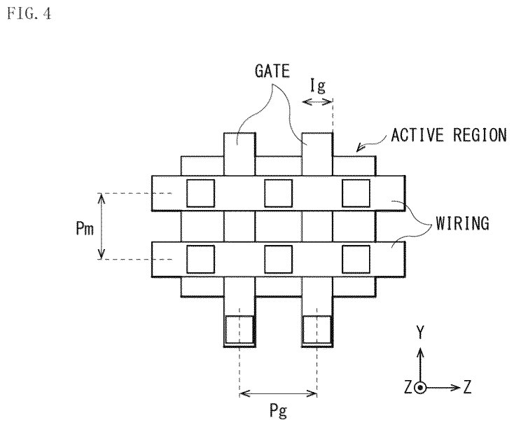

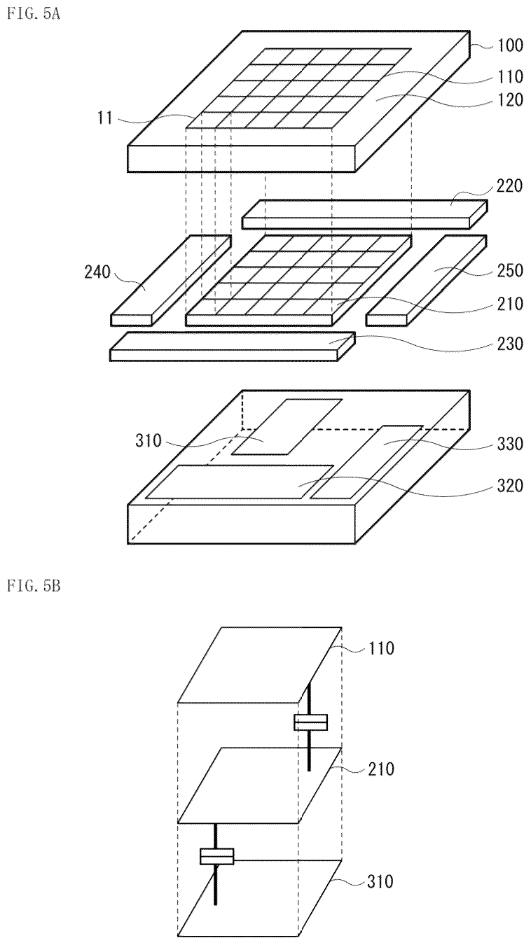

FIGS. 5A and 5B each illustrate a mode of coupling between respective circuit chips, correspond to the pixel array section 110, mounted on the first CoW layer 200 and the second CoW layer 300. The imaging device 1 has a configuration that enables analog conversion on a pixel-by-pixel basis. Specifically, for example, a signal outputted from the sensor pixel 11 is converted on a pixel-by-pixel basis in the analog circuit 210 (circuit chip C1) of the 22 nm node, for example, of the first CoW layer 200, and is subjected to execution of correction processing in the logic circuit 310 of a 14 nm node, for example, of the second CoW layer 300. The second CoW layer 300 is mounted with, for example, a logic circuit (application processor (AP) 320) and a memory (e.g., memory 330) of a 3 nm node that address AI processing, thus enabling cooperation with a learning function such as the DNN.

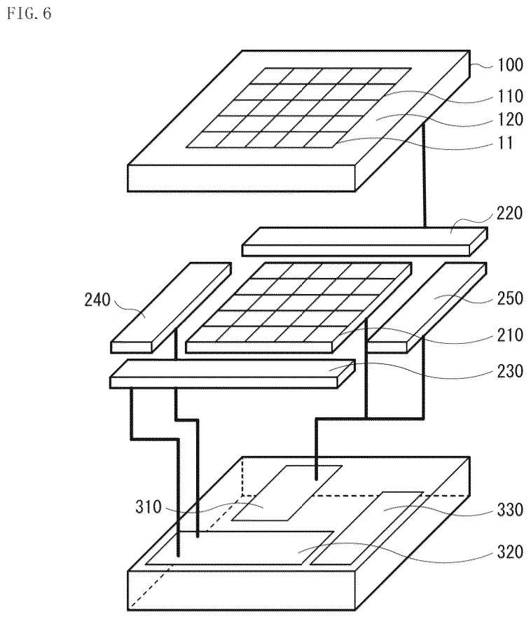

FIG. 6 illustrates an example of a mode of coupling between respective circuit chips, corresponding to the peripheral section 120, mounted on the first CoW layer 200 and the second CoW layer 300. As illustrated in FIG. 6, data processed in the logic circuit 310 and the application processor (AP) 320 of the second CoW layer 300 are respectively supplied to the logic circuits (IF circuits 220 and 250 and IF circuits 230 and 240) of the 5 nm node, for example, and are outputted to the outside through the pad electrode 13 provided in the sensor substrate 100. In addition, the application processor (AP) 320, for example, mounted on the second CoW layer 300 and the IF circuit 230, for example, mounted on the first CoW layer 200 may be coupled to each other by a plurality of pieces of coupling wiring, as illustrated in FIG. 7.

### (1-2. Manufacturing Method of Imaging Device)

The imaging device 1 of the present embodiment may be manufactured, for example, as follows.

First, as illustrated in FIG. 8A, a plurality of circuit chips constituting the logic circuit 310, the application processor (AP) 320, and the memory 330 are mounted face-down on the support substrate 340. Thereafter, an insulating film is embedded between the circuit chips to form the second CoW layer 300, and then the multilayer wiring layer 400 common to the plurality of circuit chips is formed.

Next, as illustrated in FIG. 8B, the circuit chips C1 and C2 constituting the analog circuit 210 and the IF circuits 220, 230, 240, and 250 are formed, and the circuit chips C1 and C2 are mounted face-down on the multilayer wiring layer 400, as illustrated in FIG. 8C.

Subsequently, as illustrated in FIG. 8D, the insulating film 73 is embedded between the circuit chips C1 and C2, and then the semiconductor layer 20 is thinned by chemical mechanical polishing (CMP), for example. Thereafter, the wiring layer 70 is formed that includes the pad section 72 on a surface thereof.

Next, as illustrated in FIG. 8E, the sensor substrate 100 is separately formed in which the multilayer wiring layer 40 including, on a surface thereof, the pad section 42 is formed on the first surface 10S1 of the semiconductor substrate 10. Subsequently, as illustrated in FIG. 8F, the sensor substrate 100 is coupled face-down to the first CoW layer 200. Thereafter, the semiconductor substrate 10 is thinned from the side of the second surface 10S2 by the CMP, for example, and then the opening H through which the pad electrode 13 is exposed, the color filter 51, and the light-receiving lens 52 are formed. As described above, the imaging device 1 illustrated in FIG. 1 is completed.

### (1-3. Workings and Effects)

In the imaging device 1 of the present embodiment, two layers having the chip-on-wafer (CoW) structure (the first CoW layer 200 and the second CoW layer) are stacked, below the sensor substrate 100 (on a side opposite to a light incident surface), in this order from a side of the sensor substrate 100, thus enabling mounting of the circuit chips C1 and C2 with different technology nodes on the first CoW layer 200. This enables mounting of a plurality of chips having different functions. This is described below.

In recent years, as for an image sensor, development has been made for an image sensor having a three-dimensional structure in which a sensor section and a control circuit section are stacked separately in three or more layers of chips due to an increase in the number of signal processing circuits or the like for correction in a sensor or an increase in the number of memories required to hold processed information. In addition, an image sensor has been devised that combines various functions such as a logic circuit, an analog circuit and a memory into one chip.

In a typical image sensor, a circuit chip with a single technology node of an older generation than the 22 nm node, that is able to incorporate an analog circuit including a transistor having a high power supply voltage equal to or higher than 2.5V, is arranged below a sensor chip.

Incidentally, in a case where a signal processed in an analog circuit or a logic circuit is outputted to the outside at high speed, it is difficult for the logic circuit with the 22 nm node to achieve the high-speed output; the most advanced logic circuit (IF circuit) such as the 5 nm node is required. However, as for a transistor of the Fin-FET structure, a gate-all-around (GAA) structure, or the like, which is of the 5 nm node or thereafter, it is difficult, in terms of the structure, to form a transistor including a thick gate insulating film having a power supply voltage of 2.5V or more.

In addition, in order to reduce deterioration of a signal, the IF circuit is desired to be arranged at a position close to a pad electrode for external extraction formed on a side of the sensor.

That is, it is difficult to incorporate, in one circuit chip, the most advanced logic circuit including a core transistor of the 5 nm node to which a low power supply voltage is applied with an analog circuit including a transistor to which a high power supply voltage is applied. This makes it difficult to arrange circuit blocks with different technology nodes below a sensor chip, which is an issue.

In contrast, in the present embodiment, for example, on the second CoW layer 300 mounted with a plurality of circuit chips such as the logic circuit 310 on the support substrate 340, the circuit chips C1 and C2 with different technology nodes are mounted, with the second CoW layer 300 being regarded as a wafer, which circuit chips C1 and C2 are set as the first CoW layer 200. This makes it possible to arrange, below the sensor substrate 100, the circuit chip C1 (analog circuit 210) with a technology node of an older generation than the 22 nm node, for example, and the circuit chip C2 (IF circuits 220, 230, 240, and 250) with the most advanced technology node, e.g., the 7 nm node or thereafter. That is, it becomes possible to achieve analog processing using a transistor to which a high power supply voltage is applied as well as high-speed external processing by means of the most advanced logic circuit.

As described above, it is possible, in the imaging device 1 of the present embodiment, to mount a plurality of chips having different functions with different technology nodes below the sensor substrate 100. This makes it possible to achieve a highly functional imaging device.

Hereinafter, description is given of modification examples (Modification Examples 1 to 10) of the foregoing embodiment. It is to be noted that, in the following description, the same components as those of the foregoing embodiment are denoted by the same reference numerals, and descriptions thereof are omitted as appropriate.

### 2. Modification Examples

### 2-1. Modification Example 1

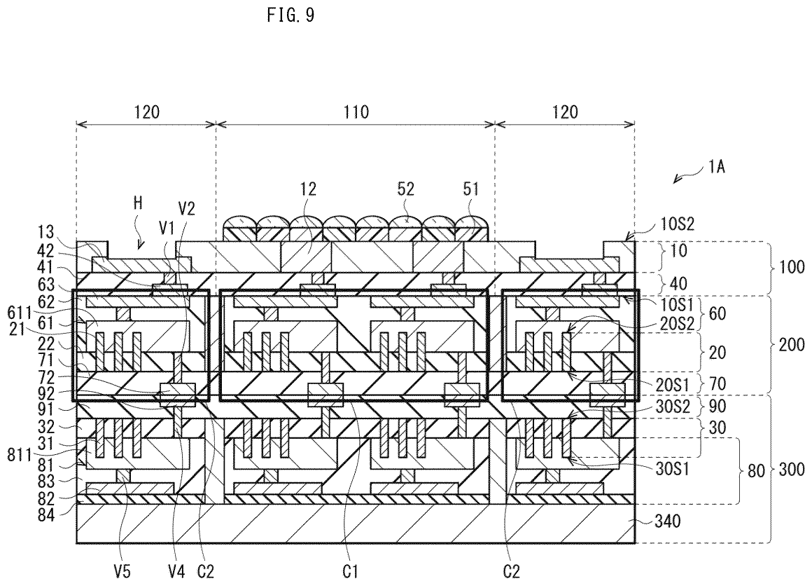

FIG. 9 schematically illustrates an example of a cross-sectional configuration of an imaging device 1A according to Modification Example 1 of the present disclosure. In the imaging device 1A, the first CoW layer 200 and the second CoW layer 300 are stacked in this order below the sensor substrate 100, in the same manner as the foregoing embodiment. The first CoW layer 200 is mounted with the circuit chips C1 and C2 with different technology nodes. The present modification example differs from the foregoing embodiment in that the circuit chips C1 and C2 of the first CoW layer 200 are stacked face-up and circuit chips of the second CoW layer 300 are stacked face-down, on the support substrate 340.

The imaging device 1A may be manufactured, for example, as follows.

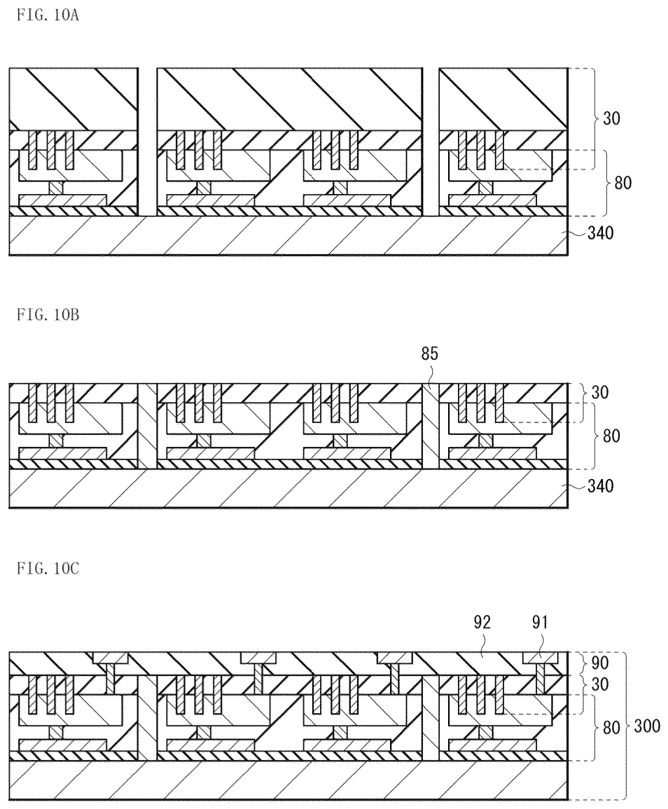

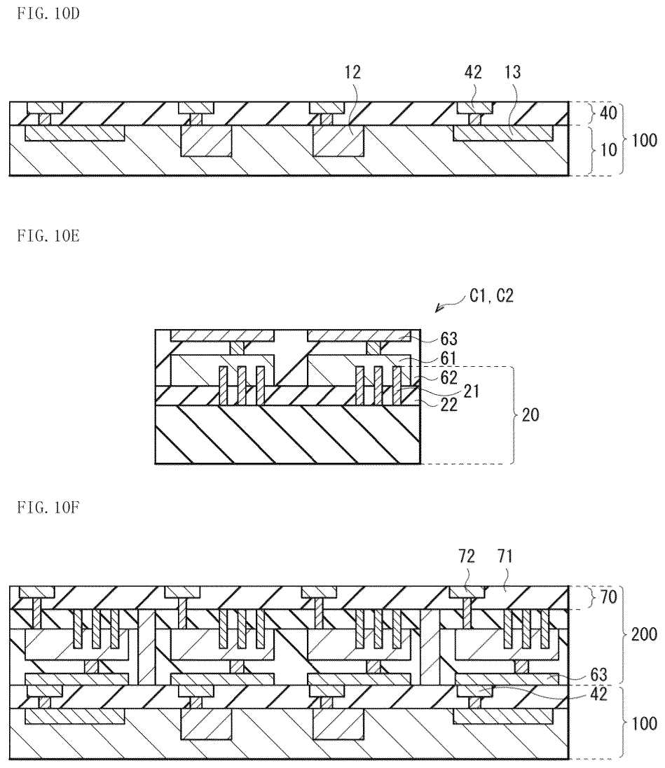

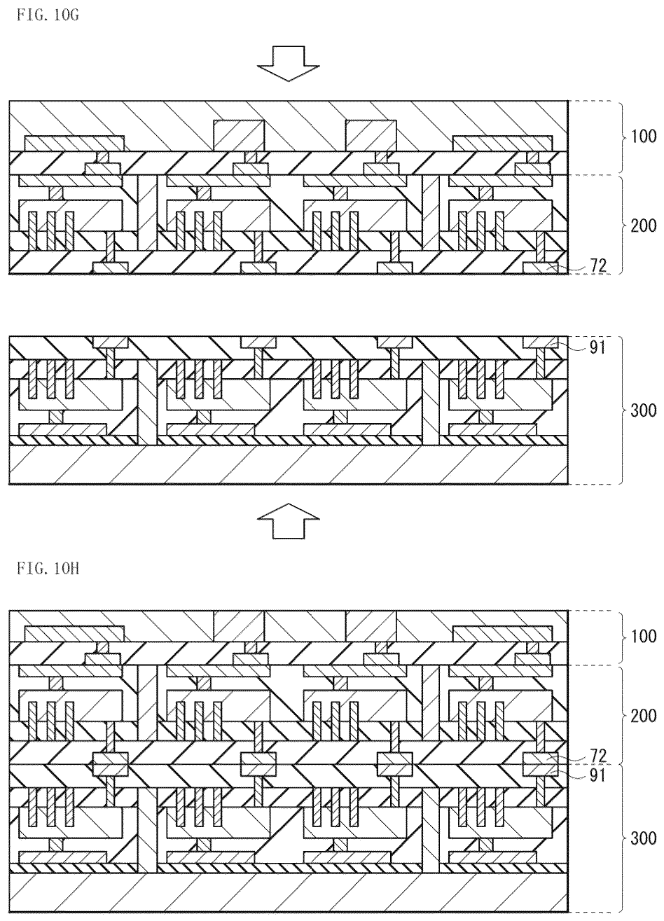

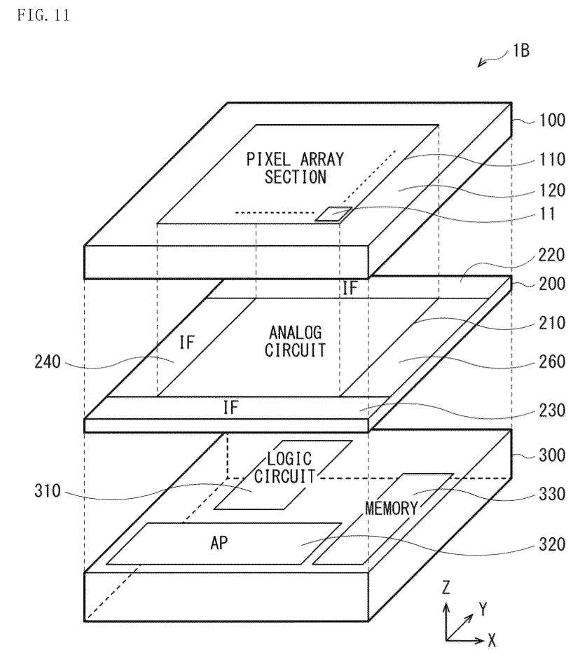

First, as illustrated in FIG. 10A, a plurality of circuit chips constituting the logic circuit 310, the application processor (AP) 320, and the memory 330 is mounted face-down on the support substrate 340. Next, as illustrated in FIG. 10B, an insulating film is embedded between the circuit chips, and then the semiconductor layer 30 is thinned by the CMP, for example.

Subsequently, as illustrated in FIG. 10C, the wiring layer 90 including, on a surface thereof, the pad section 92 is formed on the semiconductor layer 30 to form the second CoW layer 300. Next, as illustrated in FIG. 10D, the sensor substrate 100 is separately formed in which the multilayer wiring layer 40 including, on a surface thereof, the pad section 42 is formed on the first surface 10S1 of the semiconductor substrate 10.

Subsequently, as illustrated in FIG. 10E, the circuit chips C1 and C2 constituting the analog circuit 210 and the IF circuits 220, 230, 240, and 250 are formed, and, as illustrated in FIG. 10F, the circuit chips C1 and C2 are mounted face-down on the sensor substrate 100. Next, the insulating film 73 is embedded between the circuit chips C1 and C2, and then the semiconductor layer 20 is thinned by the CMP, for example. Thereafter, the wiring layer 70 is formed that includes the pad section 72 on the surface thereof.

Subsequently, as illustrated in FIG. 10G, the first CoW layer 200 on which the sensor substrate 100 is stacked and the second CoW layer 300 are attached to each other. Thereafter, as illustrated in FIG. 10H, the semiconductor substrate 10 is thinned from the side of the second surface 10S2, for example, by the CMP, and then the opening H through which the pad electrode 13 is exposed, the color filter 51, and the light-receiving lens 52 are formed. As described above, the imaging device 1A illustrated in FIG. 9 is completed.

Thus, in the imaging device 1A of the present modification example, the circuit chips C1 and C2 with different technology nodes constituting the first CoW layer 200 are stacked face-up, and a plurality of circuit chips constituting the second CoW layer 300 is stacked face-down on the support substrate 340. This makes it possible to achieve effects similar to those of the foregoing embodiment.

In addition, in a case where the number of wiring layers is large, it is possible for the imaging device 1, in which the circuit chips C1 and C2 constituting the first CoW layer 200 are mounted face-down and the circuit chips constituting the second CoW layer 300 are mounted face-down on the support substrate 340 as in the foregoing embodiment, to reduce parasitic capacitance and resistance with respect to a side of the pixels. Meanwhile, in a case where the number of wiring layers is small, it is possible for the imaging device 1A, in which the circuit chips C1 and C2 constituting the first CoW layer are stacked face-up and the circuit chips constituting the second CoW layer 300 are stacked face-down as in the present modification example, to simplify the manufacturing step.

### 2-2. Modification Example 2

FIG. 11 is an exploded perspective view of a schematic configuration of an imaging device 1B according to Modification Example 2 of the present disclosure. The foregoing embodiment describes the example in which the first CoW layer 200 is mounted with, for example, the circuit chip C1 (analog circuit 210) with a technology node of an older generation than the 22 nm node, and the chip C2 (IF circuits 220, 230, 240, and 250) with the most advanced technology node, e.g., the 5 nm node; however, this is not limitative.

For example, as illustrated in FIG. 11, a circuit chip (e.g., a most advanced logic circuit 260) with a technology node different from the IF circuits 220, 230, and 240 may be mounted above the memory 330 provided in the second CoW layer 300.

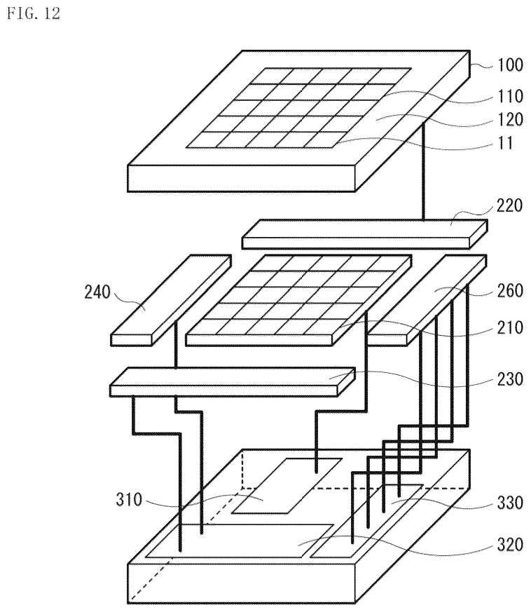

In addition, as illustrated in FIG. 12, the logic circuit 260 may be coupled to the memory 330 mounted on the second CoW layer 300 by one piece of or a plurality of pieces of coupling wiring.

This enables the coupling in a vertical direction (a Z-axis direction) to have a shorter wiring length than signal processing between a logic circuit and a memory circuit in a horizontal direction (an X-Y plane direction), as in the foregoing embodiment. It is therefore possible to decrease a delay in a signal between the logic circuit and the memory circuit and to reduce power consumption.

### 2-3. Modification Example 3

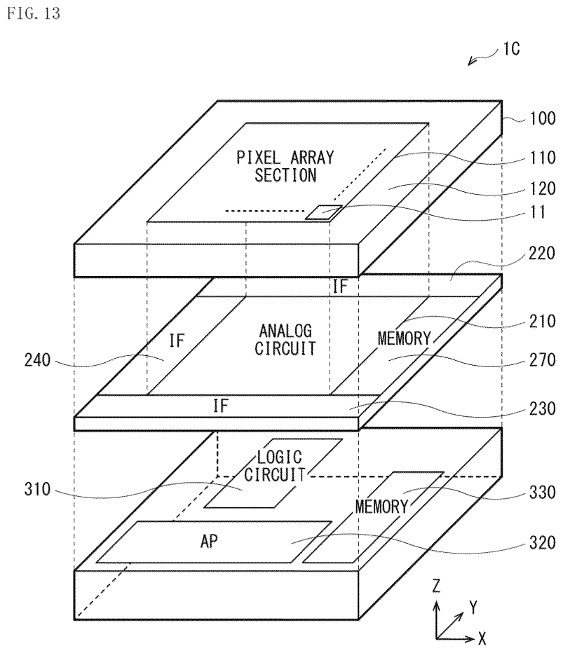

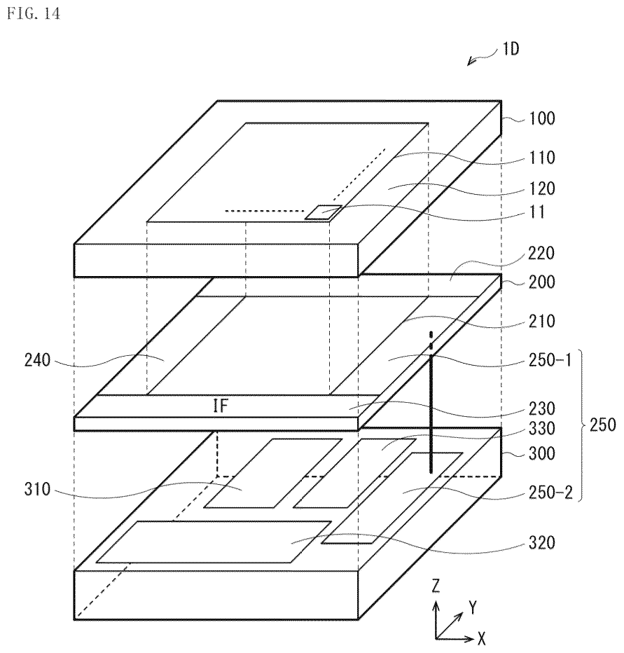

FIG. 13 is an exploded perspective view of a schematic configuration of an imaging device 1C according to Modification Example 3 of the present disclosure. The foregoing embodiment describes the example in which the first CoW layer 200 is mounted with the analog circuit 210 (circuit chip C1) and the IF circuits 220, 230, 240, and 250 (circuit chips C2). However, the first CoW layer 200 may be mounted with a circuit chip having another function.

For example, as illustrated in FIG. 13, a memory (a memory 270) such as Magnetoresistive Random Access Memory (MRAM) may be mounted as a chip.

This makes it possible to eliminate memory shortage. In addition, memory access to the application processor (AP) 320 mounted on the second CoW layer 300 is able to be three-dimensionally coupled. It is therefore possible to shorten a wiring length, thus making it possible to decrease a delay in a signal due to wiring resistance (R) and wiring capacitance (C) as well as to reduce power consumption.

### 2-4. Modification Example 4

FIG. 14 is an exploded perspective view of a schematic configuration of an imaging device 1D according to Modification Example 4 of the present disclosure. Some of the circuit chips mounted on the first CoW layer 200 may be mounted on the second CoW layer 300.

As an example, in a case where the first CoW layer 200 is not able to be mounted with the IF circuit 250 due to a large formation area thereof, for example, a circuit chip of the IF circuit 250 may be divided into two circuit chips (IF circuits 250-1 and 250-2), for example; one circuit chip may be mounted on the second CoW layer 300, and the circuit chips may be coupled to each other by one piece of or a plurality of pieces of coupling wiring, as illustrated in FIG. 14. At that time, the IF circuits 250-1 and 250-2 are preferably arranged to be closest to each other, and are preferably arranged vertically to be superposed on each other in a plan view, as illustrated in FIG. 14.

### 2-5. Modification Example 5

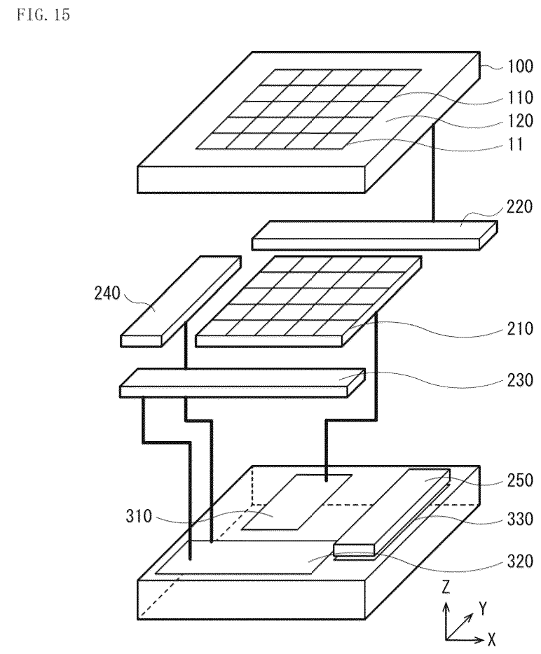

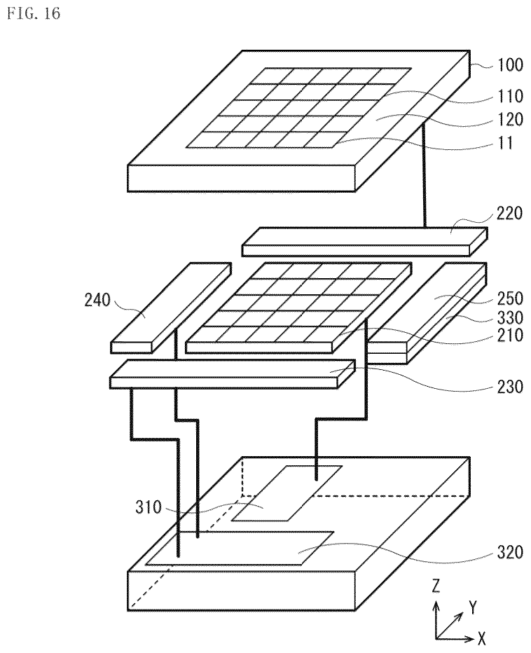

FIG. 15 is an exploded perspective view of an example of a schematic configuration of an imaging device 1E according to Modification Example 5 of the present disclosure. For example, the IF circuit 250 mounted on the first CoW layer 200 in the foregoing embodiment or the like may be mounted in advance, as a two-layer chip stacked on the memory 330, on the second CoW layer 300, as illustrated in FIG. 15.

Alternatively, as illustrated in FIG. 16, the IF circuit 250 and the memory 330 may be stacked in advance to be mounted on the first CoW layer 200.

It is to be noted that the type of chip formed as the two-layer chip as described above is not limited; circuit chips having different functions (e.g., the IF circuit 250 and the memory 330) may be stacked as described above, or circuit chips having the same function (e.g., logic circuits simultaneously) may be stacked.

### 2-6. Modification Example 6

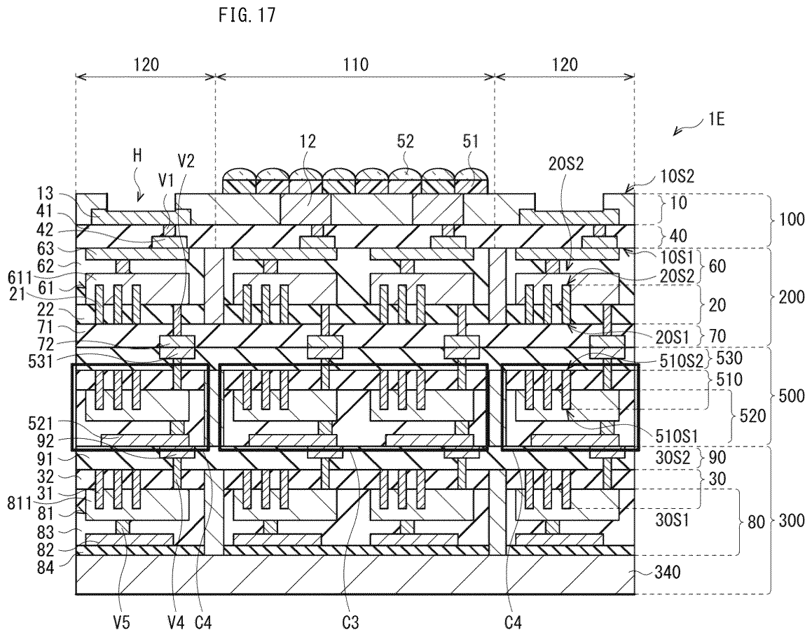

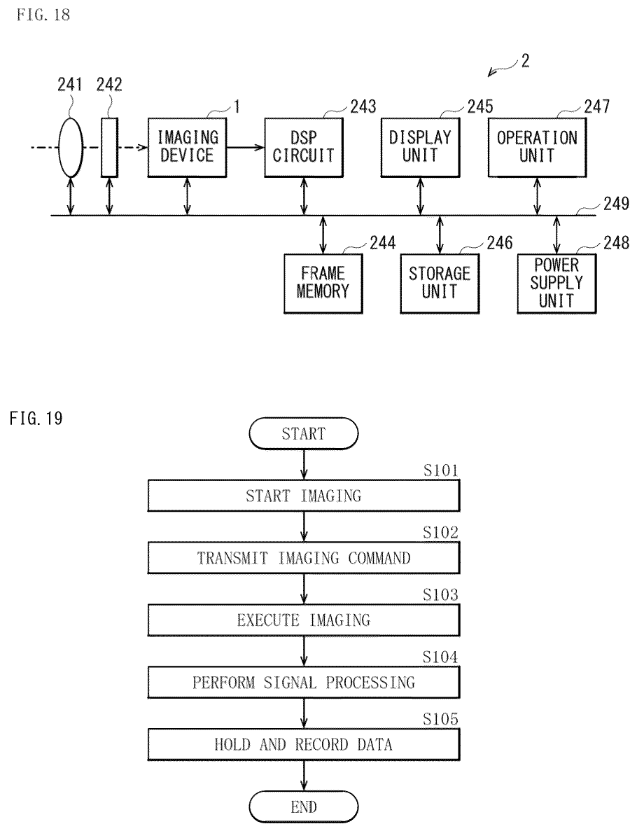

FIG. 17 schematically illustrates an example of a cross-sectional configuration of an imaging device IF according to Modification Example 6 of the present disclosure. In the foregoing embodiment, the two layers (the first CoW layer 200 and the second CoW layer 300) having a chip-on-wafer (CoW) structure are stacked below the sensor substrate 100; however, this is not limitative.

For example, as illustrated in FIG. 17, a third CoW layer 500 mounted with circuit chips C3 and C4 with different technology nodes may be disposed between the first CoW layer 200 and the second CoW layer 300.

### 2-7. Modification Example 7

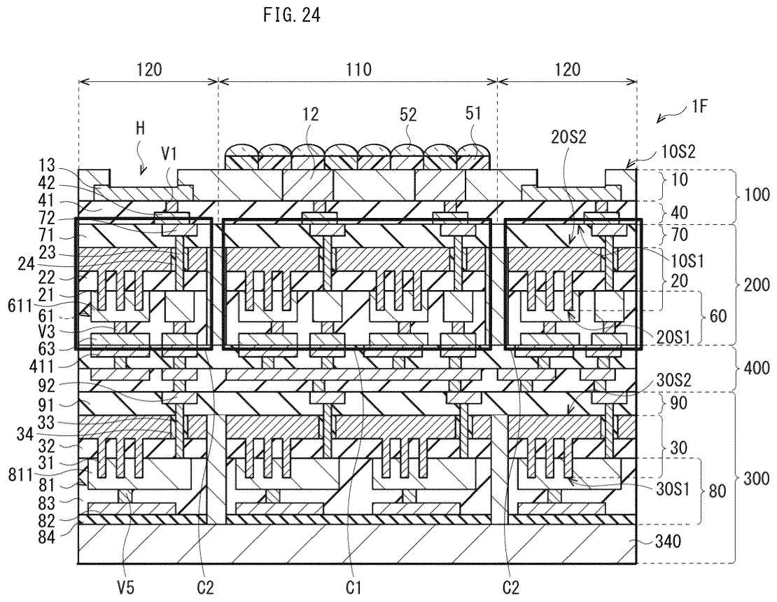

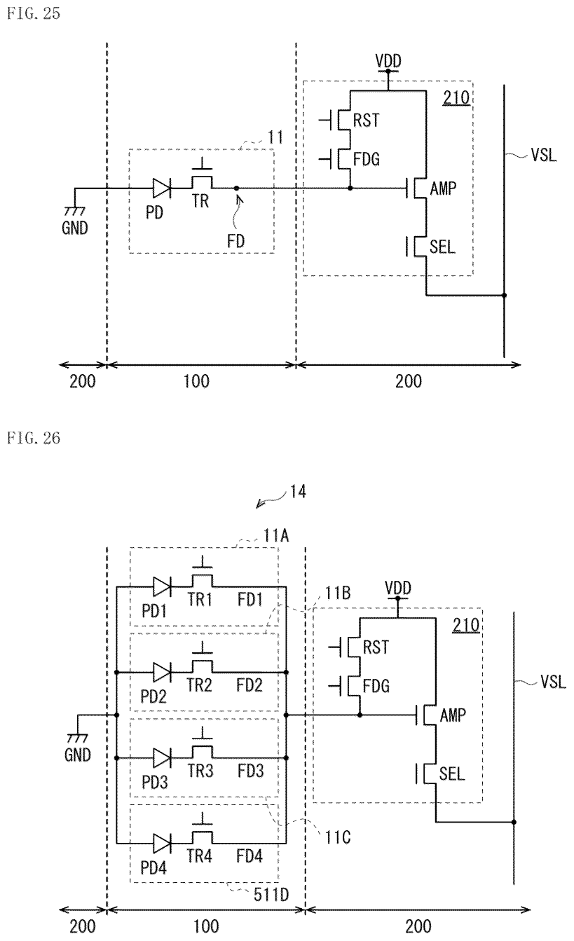

FIG. 24 schematically illustrates an example of a cross-sectional configuration of an imaging device 1F according to Modification Example 7 of the present disclosure. In the imaging device 1F, the first CoW layer 200 and the second CoW layer 300 are stacked in this order below the sensor substrate 100, in the same manner as the foregoing embodiment. The first CoW layer 200 is mounted with the circuit chips C1 and C2 with different technology nodes.

The imaging device 1 of the foregoing embodiment describes the example in which all the semiconductor layers 20 and 30 are removed except portions of fins 21 and 31 in each of circuit chips mounted on the first CoW layer 200 and the second CoW layer 300; however, this is not limitative. The imaging device 1F of the present modification example differs from the foregoing embodiment in that the semiconductor layers 20 and 30, which are continuous to lower parts of the plurality of fins 21 and 31, remain in each of the circuit chips mounted on the first CoW layer 200 and the second CoW layer 300. Further, the present modification example differs from the foregoing embodiment in that through-wiring 23 and through-wiring 33 are provided that penetrate the respective semiconductor layers 20 and 30 of the first CoW layer 200 and the second CoW layer 300.

The through-wiring 23 electrically couples the wiring 61 including the gate 611 provided on the side of the front surface 20S1 of the semiconductor layer 20 to the pad section 72 for use in attaching to the sensor substrate 100. The through-wiring 23 that penetrates the semiconductor layer 20 is electrically insulated, by an insulating film 24 provided therearound, from the semiconductor layer 20. The through-wiring 33 electrically couples the wiring 81 including the gate 811 provided on the side of the front surface 30S1 of the semiconductor layer 30 to the pad section 92 for use in attaching to the first CoW layer 200. The through-wiring 33 that penetrates the semiconductor layer 30 is electrically insulated, by an insulating film 34 provided therearound, from the semiconductor layer 30.

One piece of or a plurality of pieces of through-wiring 23 is provided for each of the sensor pixels 11 or for every plurality of sensor pixels 11. FIGS. 25 and 26 each illustrate an example of an equivalent circuit diagram in the pixel array section 110. For example, as illustrated in FIG. 25, in a case where, for example, the analog circuit 210 (e.g., pixel circuit) including four transistors, specifically, an amplification transistor AMP, a selection transistor SEL, a reset transistor RST, and an FD conversion gain switching transistor FDG is provided for one sensor pixel 11, one through-wiring 23 that couples the floating diffusion FD to a gate of the amplification transistor AMP, for example, is provided for each of the sensor pixels 11. For example, as illustrated in FIG. 26, in a case where the plurality of sensor pixels 11 (four sensor pixels 11A, 11B, 11C, and 11D in FIG. 26) shares one analog circuit 210, one through-wiring 23 is provided for each of the four sensor pixels 11 to cause respective floating diffusions FD1, FD2, FD3, and FD4 of the sensor pixels 11A, 11B, 11C, and 11D to be coupled to the gate of the amplification transistor AMP, for example. The same applies to the through-wiring 33. It is to be noted that the through-wiring 23 is not limited to the wiring that couples the floating diffusion FD and the analog circuit 210 to each other; however, the through-wiring 23 also includes wiring or the like that couples the semiconductor substrate 10 and a reference potential line to each other in order to supply a reference potential to the semiconductor substrate 10 constituting the sensor substrate 100, for example. In addition, in the same manner as the through-wiring 23 described above, one or a plurality of vias V2 according to the foregoing embodiment and the like is provided for each of the sensor pixels 11 or for every plurality of sensor pixels 11.

The through-wiring 23 and the through-wiring 33 each include, for example, an electrically-conductive layer and a barrier layer serving also as an adhesion layer. Examples of a material of the electrically-conductive layer include tungsten (W), cobalt (Co), ruthenium (Ru), copper (Cu), aluminum (Al), and molybdenum (Mo). The barrier layer is formed to include one or all of tantalum (Ta), titanium (Ti), and nitrogen (N), for example. The through-wiring 23 and the through-wiring 33 are formed, for example, by forming a barrier layer, as a film, and then forming an electrically-conductive layer, as a film, using, for example, a CVD method to fill a through-hole. The through-wiring 23 and the through-wiring 33 each have, in general, a diameter of 70 nm, for example, but may have a size of 10 nm to 500 nm.

Thus, in the imaging device 1F of the present modification example, the semiconductor layers 20 and 30 continuous to the lower parts of the plurality of fins 21 and 31 remain in each of the circuit chips mounted on the first CoW layer 200 and the second CoW layer 300. This enables formation of a contact region to apply a reference potential to each of the semiconductor layers 20 and 30, in addition to the effects of the foregoing embodiments, thus making it possible to use a ground potential on each of the circuits.

### 2-8. Modification Example 8

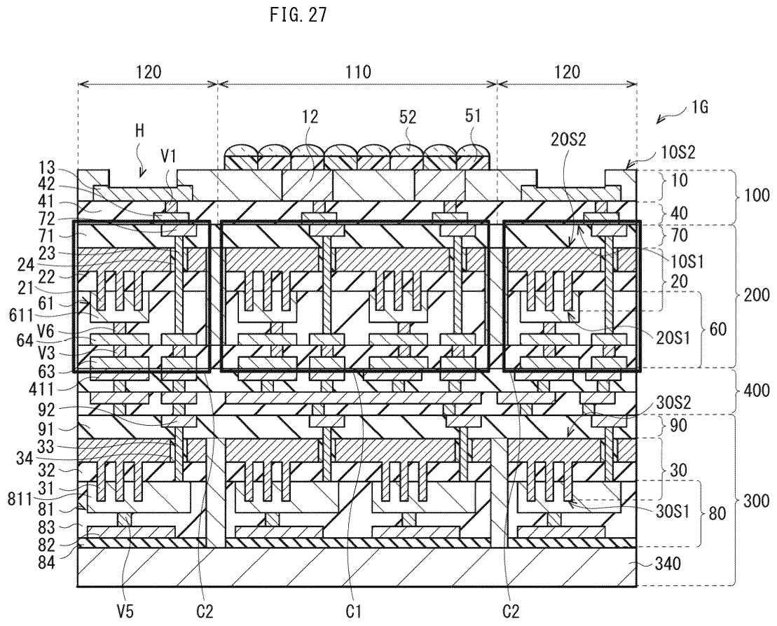

FIG. 27 schematically illustrates an example of a cross-sectional configuration of an imaging device 1G according to Modification Example 8 of the present disclosure. In the imaging device 1G, the first CoW layer 200 and the second CoW layer 300 are stacked in this order below the sensor substrate 100, in the same manner as the foregoing embodiment. The first CoW layer 200 is mounted with the circuit chips C1 and C2 with different technology nodes.

The imaging device IF according to the foregoing Modification Example 7 describes the example in which the through-wiring 23 is coupled to the wiring 61 including the gate 611; however, this is not limitative. In the imaging device 1G according to the present modification example, the through-wiring 23 couples wiring 64 and the pad section 72 to each other. The wiring 64 is provided above the wiring 61, and is formed using a metal material such as Cu, W, Co, Ru, Mo, or Al, and the pad section 72 is used for attaching to the sensor substrate 100.

Also in such a configuration, it is possible to achieve effects similar to those of the foregoing embodiment.

### 2-9. Modification Example 9

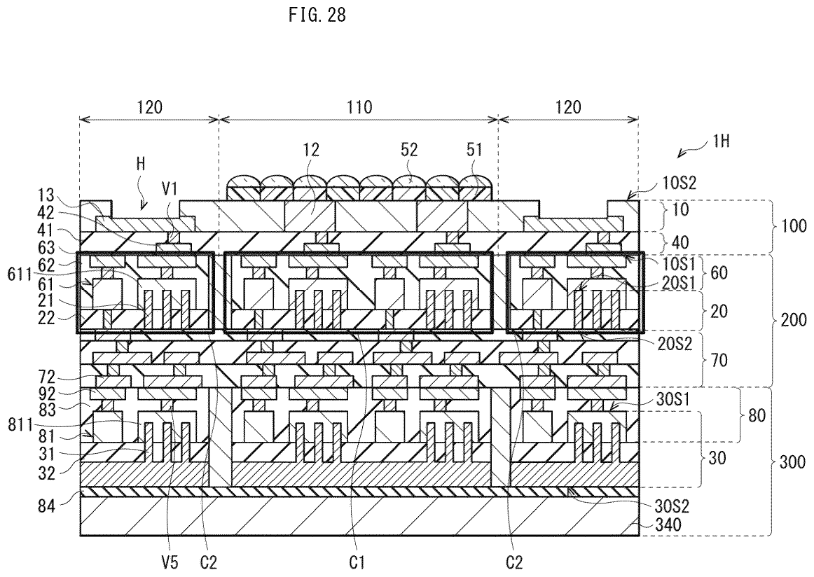

FIG. 28 schematically illustrates an example of a cross-sectional configuration of an imaging device 1H according to Modification Example 9 of the present disclosure. In the imaging device 1H, the first CoW layer 200 and the second CoW layer 300 are stacked in this order below the sensor substrate 100, in the same manner as the foregoing embodiment. The first CoW layer 200 is mounted with the circuit chips C1 and C2 with different technology nodes.

The imaging device 1H according to the present modification example differs from the foregoing embodiment in that the circuit chips C1 and C2 of the first CoW layer 200 and the circuit chips of the second CoW layer 300 are each stacked face-up on the support substrate 340. In other words, the sensor substrate 100 and the first CoW layer 200 are stacked face-to-face to allow the first surface 10S1 of the semiconductor substrate 10 and the front surface 20S1 of the semiconductor layer 20 to be opposed to each other. The first CoW layer 200 and the second CoW layer 300 are stacked back-to-face to allow the back surface 20S2 of the semiconductor layer 20 and the front surface 30S1 of the semiconductor layer 30 to be opposed to each other.

Also in such a configuration, it is possible to achieve effects similar to those of the foregoing embodiment.

### 2-10. Modification Example 10

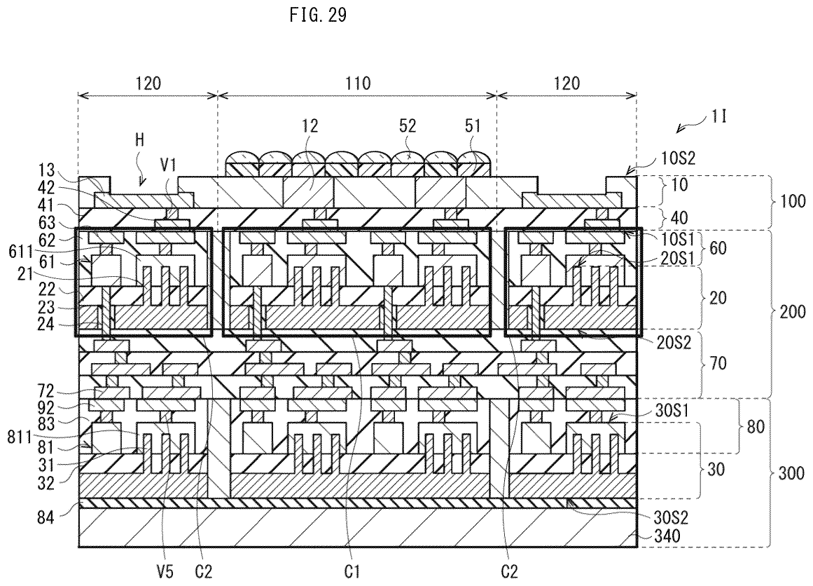

FIG. 29 schematically illustrates an example of a cross-sectional configuration of an imaging device 1I according to Modification Example 10 of the present disclosure. In the imaging device 1I, the first CoW layer 200 and the second CoW layer 300 are stacked in this order below the sensor substrate 100, in the same manner as the foregoing embodiment. The first CoW layer 200 is mounted with the circuit chips C1 and C2 with different technology nodes.

The foregoing Modification Example 9 describes the example in which all the semiconductor layers 20 are removed except a portion of the fin 21 in each of the circuit chips mounted on the first CoW layer 200; however, this is not limitative. In the imaging device 1I according to the present modification example, in the same manner as Modification Example 7, the semiconductor layers 20 continuous to the lower parts of the plurality of fins 21 remain in each of the circuit chips mounted on the first CoW layer 200, and the first CoW layer 200 and the second CoW layer 300 are electrically coupled to each other using the through-wiring 23 that penetrates the semiconductor layer 20.

This makes it possible, in the imaging device IF according to the present modification example, to form a contact region to apply a reference potential to each of the semiconductor layers 20 and 30, in addition to the effects of the foregoing embodiment, thus making it possible to use a ground potential on each of the circuits, in the same manner as the foregoing Modification Example 7.

### 3. Application Example

FIG. 18 illustrates an example of a schematic configuration of an imaging system 2 including the imaging device (e.g., the imaging device 1) according to any of the foregoing embodiment and Modification Examples 1 to 10.

The imaging system 2 is an electronic apparatus including, for example, a camera such as a digital still camera or a video camera, or a portable terminal apparatus such as a smartphone or a tablet-type terminal. The imaging system 2 includes, for example, the imaging device (e.g., the imaging device 1) according to any of the foregoing embodiment and the modification examples thereof, an optical system 241, a shutter device 242, a DSP circuit 243, a frame memory 244, a display unit 245, a storage unit 246, an operation unit 247, and a power supply unit 248. In the imaging system 2, the imaging device 1 according to any of the foregoing embodiment and the modification examples thereof, the DSP circuit 243, the frame memory 244, the display unit 245, the storage unit 246, the operation unit 247, and the power supply unit 248 are coupled to one another via a bus line 249.

The imaging device (e.g., the imaging device 1) according to any of the foregoing embodiment and the modification examples thereof outputs image data corresponding to incident light. The optical system 241 includes one or a plurality of lenses, and guides light (incident light) from a subject to the imaging device 1 to form an image on a light-receiving surface of the imaging device 1. The shutter device 242 is disposed between the optical system 241 and the imaging device 1, and controls periods of light irradiation and light blocking with respect to the imaging device 1 under the control of the drive circuit. The DSP circuit 243 is a signal processing circuit that processes a signal (image data) outputted from the imaging device 1. The frame memory 244 temporarily holds the image data processed by the DSP circuit 243 in a frame unit. The display unit 245 includes, for example, a panel-type display device such as a liquid crystal panel or an organic EL (Electro Luminescence) panel, and displays a moving image or a still image captured by the imaging device 1. The storage unit 246 records image data of a moving image or a still image captured by the imaging device 1 in a recording medium such as a semiconductor memory or a hard disk. The operation unit 247 issues an operation command for various functions of the imaging system 2 in accordance with an operation by a user. The power supply unit 248 appropriately supplies various types of power for operation to the imaging device 1, the DSP circuit 243, the frame memory 244, the display unit 245, the storage unit 246, and the operation unit 247 which are supply targets.

Next, description is given of an imaging procedure in the imaging system 2.

FIG. 19 illustrates an example of a flowchart of an imaging operation in the imaging system 2. A user instructs start of imaging by operating the operation unit 247 (step S101). Then, the operation unit 247 transmits an imaging command to the imaging device 1 (step S102). The imaging device 1 (specifically, a system control circuit) executes imaging in a predetermined imaging method upon receiving the imaging command (step S103).

The imaging device 1 outputs image data obtained by the imaging to the DSP circuit 243. As used herein, the image data refers to data for all pixels of pixel signals generated on the basis of electric charge temporarily held in the floating diffusion FD. The DSP circuit 243 performs predetermined signal processing (e.g., noise reduction processing, etc.) on the basis of the image data inputted from the imaging device 1 (step S104). The DSP circuit 243 causes the frame memory 244 to hold the image data having been subjected to the predetermined signal processing, and the frame memory 244 causes the storage unit 246 to store the image data (step S105). In this manner, the imaging in the imaging system 2 is performed.

In the present application example, the imaging device (e.g., the imaging device 1) according to any of the foregoing embodiment and Modification Examples 1 to 10 thereof is applied to the imaging system 2. This enables smaller size or higher definition of the imaging device 1, thus making it possible to provide a small or high-definition imaging system 2.

### 4. Examples of Practical Applications

### (Example of Practical Application to Mobile Body)

The technology according to an embodiment of the present disclosure (present technology) is applicable to various products. For example, the technology according to an embodiment of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, an unmanned aerial vehicle (drone), a vessel, and a robot.

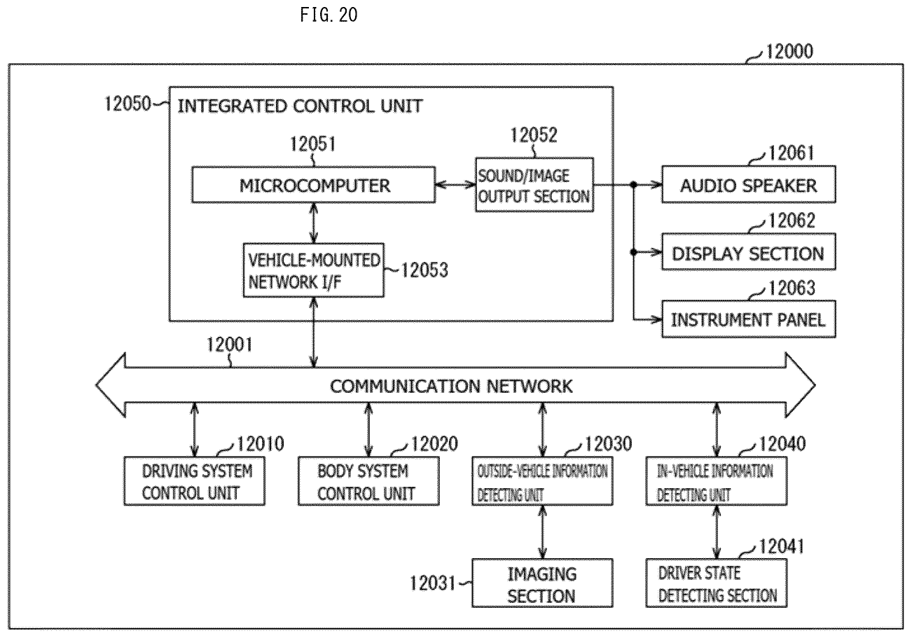

FIG. 20 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 20, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 57, an audio speaker 12061, a display section 12062, and an instrument panel 12063 are illustrated as the output device. The display section 12062 may, for example, include at least one of an on-board display and a head-up display.

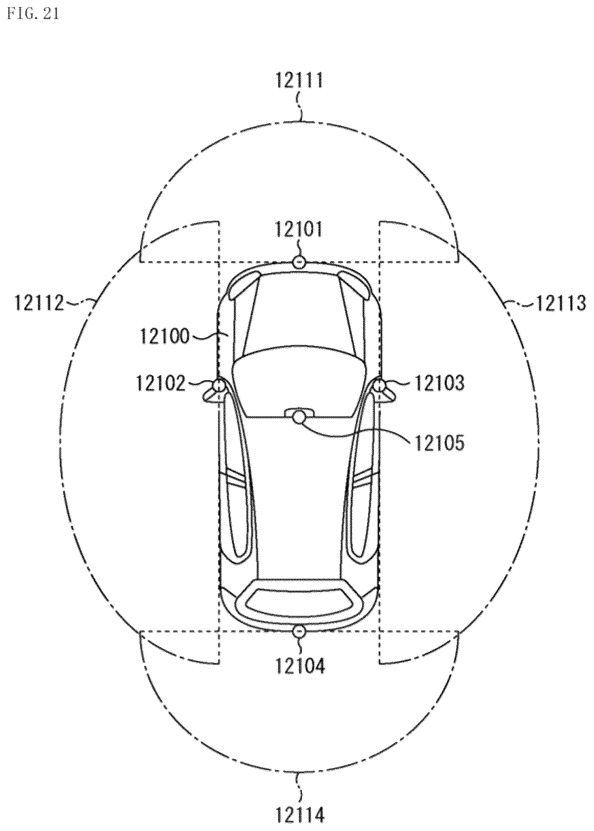

FIG. 21 is a diagram depicting an example of the installation position of the imaging section 12031.

In FIG. 21, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 21 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of one example of the mobile body control system, to which the technology according to an embodiment of the present disclosure may be applied. The technology according to an embodiment of the present disclosure may be applied to the imaging section 12031 among components of the configuration described above. Specifically, the imaging device 1 according to any of the foregoing embodiment and modification examples thereof is applicable to the imaging section 12031. Applying the technology according to an embodiment of the present disclosure to the imaging section 12031 allows for a high-definition captured image with less noise, thus making it possible to perform highly accurate control utilizing the captured image in the mobile body control system.

### (Example of Practical Application to Endoscopic Surgery System)

The technology according to an embodiment of the present disclosure (present technology) is applicable to various products. For example, the technology according to an embodiment of the present disclosure may be applied to an endoscopic surgery system.

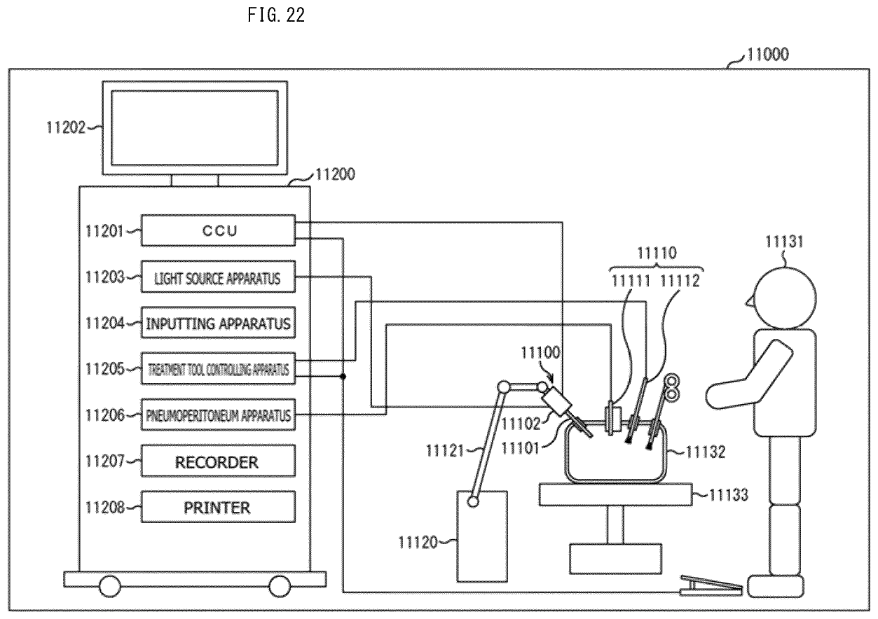

FIG. 22 is a view depicting an example of a schematic configuration of an endoscopic surgery system to which the technology according to an embodiment of the present disclosure (present technology) can be applied.

In FIG. 22, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

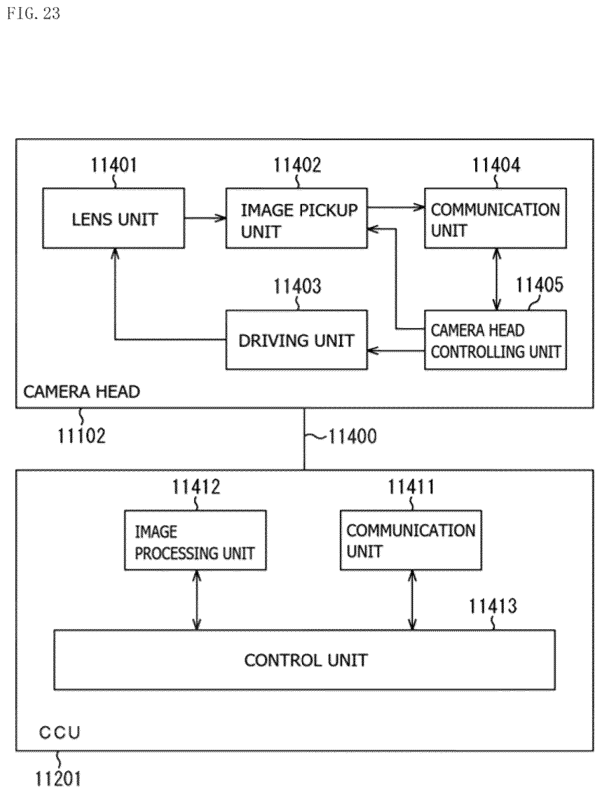

FIG. 23 is a block diagram depicting an example of a functional configuration of the camera head 11102 and the CCU 11201 depicted in FIG. 22.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to an embodiment of the present disclosure is applicable. The technology according to an embodiment of the present disclosure is suitably applicable to, for example, the image pickup unit 11402 provided in the camera head 11102 of the endoscope 11100, among the configurations described above. Applying the technology according to an embodiment of the present disclosure to the image pickup unit 11402 enables miniaturization or higher definition of the image pickup unit 11402, thus making it possible to provide the miniaturized or high-definition endoscope 11100.

Although the description has been given hereinabove of the present disclosure with reference to the embodiment and Modification Examples 1 to 10, the application example, and the practical application examples, the present disclosure is not limited to the foregoing embodiment, etc., and may be modified in a wide variety of ways.

It is to be noted that the effects described herein are merely illustrative. The effects of the present disclosure are not limited to those described herein. The present disclosure may have other effects than those described herein.

It is to be noted that the present disclosure may also have the following configurations. According to the present technology of the following configurations, a first structure layer having a chip-on-wafer structure and being mounted with a first circuit chip and a second circuit chip that have different technology nodes is stacked on a second structure layer having a chip-on-wafer structure. This enables mounting of a plurality of chips having different functions. It is therefore possible to achieve a semiconductor device and an imaging device that enable higher functionality.

(1)

A semiconductor device including:
a first structure layer having a chip-on-wafer structure and being mounted with a first circuit chip and a second circuit chip that have different technology nodes; and
a second structure layer having a chip-on-wafer structure and being stacked on the first structure layer.
   (2)

The semiconductor device according to (1), in which the first circuit chip and the second circuit chip have different minimum power supply voltages.

(3)

The semiconductor device according to (1) or (2), in which the first circuit chip and the second circuit chip include respective ones or pluralities of transistors that include insulating films having different film thicknesses.

(4)

The semiconductor device according to any one of (1) to (3), in which the first circuit chip and the second circuit chip include respective pluralities of transistors having different minimum gate pitches.

(5)

The semiconductor device according to any one of (1) to (4), in which the first circuit chip and the second circuit chip have different respective minimum wiring pitches.

(6)

The imaging device according to any one of (1) to (5), in which the first structure layer further includes a third circuit chip having a multilayer structure in which circuits having a same function or different functions are formed to be stacked.

(7)

The imaging device according to any one of (1) to (6), in which the second structure layer further includes a fourth circuit chip having a multilayer structure in which circuits having a same function or different functions are formed to be stacked.

(8)

An imaging device including:
a sensor substrate including one or a plurality of sensor pixels that performs photoelectric conversion;
a first structure layer stacked on the sensor substrate and being mounted with a first circuit chip and a second circuit chip that have different technology nodes; and
a second structure layer having a chip-on-wafer structure and being stacked on the first structure layer.
   (9)

The imaging device according to (8), in which
the sensor substrate further includes
   a pixel array section in which the one or the plurality of sensor pixels is arranged in array, and
   a peripheral section provided around the pixel array section, the first circuit chip is arranged in the pixel array section in a plan view, and the second circuit chip is arranged in the peripheral section in a plan view.
      (10)

The imaging device according to (9), in which
the first circuit chip includes an analog circuit that amplifies a pixel signal generated in the one or the plurality of sensor pixels and performs conversion into a digital signal, and
the second circuit chip includes an interface circuit that outputs the digital signal to an outside.
   (11)

The imaging device according to (10), in which the analog circuit is provided in a pixel unit or in a sharing pixel unit for sharing a charge-holding section that temporarily holds electric charge outputted from the sensor pixels.

(12)

The imaging device according to (11), further including one piece of or a plurality of pieces of through-wiring that penetrates the first circuit chip, in which
the analog circuit is electrically coupled via the one piece of or the plurality of pieces of through-wiring in the pixel unit or in the sharing pixel unit.
   (13)

The imaging device according to any one of (10) to (12), in which the second structure layer includes a fifth circuit chip provided with a first logic circuit that performs correction processing and signal modulation processing on the digital signal converted in the analog circuit.

(14)

The imaging device according to (13), in which the second structure layer further includes
a sixth circuit chip including a second logic circuit that performs machine learning, and
a first memory chip that stores data obtained by the machine learning.
   (15)

The imaging device according to any one of (8) to (14), in which
the sensor substrate includes
   a semiconductor substrate having a first surface serving as a light incident surface and a second surface on a side opposite to the first surface, the semiconductor substrate being provided with the one or the plurality of sensor pixels, and
   a multilayer wiring layer provided on a side of the second surface,
the first structure layer is stacked and includes a first semiconductor layer that constitutes transistors provided in the first circuit chip and the second circuit chip, the first semiconductor layer having a back surface that is opposed to the second surface of the semiconductor substrate, and
the second structure layer is stacked on the first structure layer and includes a second semiconductor layer that constitutes transistors provided on the mounted chips, the second semiconductor layer having a back surface that is opposed to a front surface of the first semiconductor layer.
   (16)

The imaging device according to any one of (8) to (14), in which
the sensor substrate includes
   a semiconductor substrate having a first surface serving as a light incident surface and a second surface on a side opposite to the first surface, the semiconductor substrate being provided with the one or the plurality of sensor pixels, and
   a multilayer wiring layer provided on a side of the second surface,
the first structure layer is stacked and includes a first semiconductor layer that constitutes transistors provided in the first circuit chip and the second circuit chip, the first semiconductor layer having a front surface that is opposed to the second surface of the semiconductor substrate, and
the second structure layer is stacked on the first structure layer and includes a second semiconductor layer that constitutes transistors provided on mounted chips, the second semiconductor layer having a back surface that is opposed to a back surface of the first semiconductor layer.
   (17)

The imaging device according to any one of (8) to (14), in which
the sensor substrate includes
   a semiconductor substrate having a first surface serving as a light incident surface and a second surface on a side opposite to the first surface, the semiconductor substrate being provided with the one or the plurality of sensor pixels, and
   a multilayer wiring layer provided on a side of the second surface,
the first structure layer is stacked and includes a first semiconductor layer that constitutes transistors provided in the first circuit chip and the second circuit chip, the first semiconductor layer having a front surface that is opposed to the second surface of the semiconductor substrate, and
the second structure layer is stacked on the first structure layer and includes a second semiconductor layer that constitutes transistors provided on mounted chips, the second semiconductor layer having a front surface that is opposed to a back surface of the first semiconductor layer.
   (18)

The imaging device according to any one of (8) to (17), in which
the sensor substrate and the first structure layer are attached and electrically coupled to each other by metal bonding, and
the first structure layer and the second structure layer are attached and electrically coupled to each other by metal bonding.
   (19)

The imaging device according to any one of (10) to (18), in which the first structure layer further includes a third logic circuit having a different technology node that is different from the interface circuit.

(20)

The imaging device according to any one of (8) to (19), in which the first structure layer further includes a second memory chip.

(21)

A semiconductor device including:
a first structure layer mounted with a first circuit chip and a second circuit chip that have different technology nodes; and
a second structure layer stacked on the first structure layer and being mounted with a plurality of chips.
   (22)

The semiconductor device according to (21), in which the first structure layer further includes an insulating film provided between the first circuit chip and the second circuit chip.

(23)

The semiconductor device according to (21) or (22), in which the first circuit chip includes at least a first semiconductor layer and a first wiring layer.

(24)

The semiconductor device according to any one of (21) to (23), in which the second circuit chip includes at least a second semiconductor layer and a second wiring layer.

The present application claims the benefit of Japanese Priority Patent Application JP2022-097554 filed with the Japan Patent Office on Jun. 16, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A semiconductor device, comprising:
a first structure layer having a chip-on-wafer structure and being mounted with a first circuit chip and a second circuit chip that have different technology nodes; and
a second structure layer having a chip-on-wafer structure and being stacked on the first structure layer.

2. The semiconductor device according to claim 1, wherein the first circuit chip and the second circuit chip have different minimum power supply voltages.

3. The semiconductor device according to claim 1, wherein the first circuit chip and the second circuit chip include respective ones or pluralities of transistors that include insulating films having different film thicknesses.

4. The semiconductor device according to claim 1, wherein the first circuit chip and the second circuit chip include respective pluralities of transistors having different minimum gate pitches.

5. The semiconductor device according to claim 1, wherein the first circuit chip and the second circuit chip have different respective minimum wiring pitches.

6. The semiconductor device according to claim 1, wherein the first structure layer is further mounted with a third circuit chip having a multilayer structure in which circuits having a same function or different functions are formed to be stacked.

7. The semiconductor device according to claim 1, wherein the second structure layer is further mounted with a fourth circuit chip having a multilayer structure in which circuits having a same function or different functions are formed to be stacked.

8. An imaging device, comprising:
a sensor substrate including one or a plurality of sensor pixels that performs photoelectric conversion;
a first structure layer stacked on the sensor substrate and being mounted with a first circuit chip and a second circuit chip that have different technology nodes; and
a second structure layer having a chip-on-wafer structure and being stacked on the first structure layer.

9. The imaging device according to claim 8, wherein
the sensor substrate further includes
a pixel array section in which the one or the plurality of sensor pixels is arranged in array, and
a peripheral section provided around the pixel array section,
the first circuit chip is arranged in the pixel array section in a plan view, and
the second circuit chip is arranged in the peripheral section in a plan view.

10. The imaging device according to claim 9, wherein
the first circuit chip includes an analog circuit that amplifies a pixel signal generated in the one or the plurality of sensor pixels and performs conversion into a digital signal, and
the second circuit chip includes an interface circuit that outputs the digital signal to an outside.

11. The imaging device according to claim 10, wherein the analog circuit is provided in a pixel unit or in a sharing pixel unit for sharing a charge-holding section that temporarily holds electric charge outputted from the sensor pixels.

12. The imaging device according to claim 11, further comprising one piece of or a plurality of pieces of through-wiring that penetrates the first circuit chip, wherein
the analog circuit is electrically coupled via the one piece of or the plurality of pieces of through-wiring in the pixel unit or in the sharing pixel unit.

13. The imaging device according to claim 10, wherein the second structure layer includes a fifth circuit chip provided with a first logic circuit that performs correction processing and signal modulation processing on the digital signal converted in the analog circuit.

14. The imaging device according to claim 13, wherein the second structure layer further includes
a sixth circuit chip including a second logic circuit that performs machine learning, and
a first memory chip that stores data obtained by the machine learning.

15. The imaging device according to claim 8, wherein
the sensor substrate includes
a semiconductor substrate having a first surface serving as a light incident surface and a second surface on a side opposite to the first surface, the semiconductor substrate being provided with the one or the plurality of sensor pixels, and
a multilayer wiring layer provided on a side of the second surface,
the first structure layer is stacked and includes a first semiconductor layer that constitutes transistors provided in the first circuit chip and the second circuit chip, the first semiconductor layer having a back surface that is opposed to the second surface of the semiconductor substrate, and
the second structure layer is stacked on the first structure layer and includes a second semiconductor layer that constitutes transistors provided on mounted chips, the second semiconductor layer having a back surface that is opposed to a front surface of the first semiconductor layer.

16. The imaging device according to claim 8, wherein
the sensor substrate includes
a semiconductor substrate having a first surface serving as a light incident surface and a second surface on a side opposite to the first surface, the semiconductor substrate being provided with the one or the plurality of sensor pixels, and
a multilayer wiring layer provided on a side of the second surface,
the first structure layer is stacked and includes a first semiconductor layer that constitutes transistors provided in the first circuit chip and the second circuit chip, the first semiconductor layer having a front surface that is opposed to the second surface of the semiconductor substrate, and
the second structure layer is stacked on the first structure layer and includes a second semiconductor layer that constitutes transistors provided on mounted chips, the second semiconductor layer having a back surface that is opposed to a back surface of the first semiconductor layer.

17. The imaging device according to claim 8, wherein
the sensor substrate includes
a semiconductor substrate having a first surface serving as a light incident surface and a second surface on a side opposite to the first surface, the semiconductor substrate being provided with the one or the plurality of sensor pixels, and
a multilayer wiring layer provided on a side of the second surface,
the first structure layer is stacked and includes a first semiconductor layer that constitutes transistors provided in the first circuit chip and the second circuit chip, the first semiconductor layer having a front surface that is opposed to the second surface of the semiconductor substrate, and
the second structure layer is stacked on the first structure layer and includes a second semiconductor layer that constitutes transistors provided on mounted chips, the second semiconductor layer having a front surface that is opposed to a back surface of the first semiconductor layer.

18. The imaging device according to claim 8, wherein
the sensor substrate and the first structure layer are attached and electrically coupled to each other by metal bonding, and
the first structure layer and the second structure layer are attached and electrically coupled to each other by metal bonding.

19. The imaging device according to claim 10, wherein the first structure layer further includes a third logic circuit having a different technology node that is different from the interface circuit.

20. The imaging device according to claim 8, wherein the first structure layer further includes a second memory chip.

21. A semiconductor device, comprising:
a first structure layer mounted with a first circuit chip and a second circuit chip that have different technology nodes; and
a second structure layer stacked on the first structure layer and being mounted with a plurality of chips.

22. The semiconductor device according to claim 21, wherein the first structure layer further includes an insulating film provided between the first circuit chip and the second circuit chip.

23. The semiconductor device according to claim 21, wherein the first circuit chip includes at least a first semiconductor layer and a first wiring layer.

24. The semiconductor device according to claim 21, wherein the second circuit chip includes at least a second semiconductor layer and a second wiring layer.
